(19) United States
(12) Patent Application Publication
(10) Pub. No.: US 2024/0355662 A1
(43) Pub. Date: Oct. 24, 2024

(54) JIG SUBSTRATE AND TEACHING METHOD

(71) Applicant: TOKYO ELECTRON LIMITED, Tokyo (JP)

(72) Inventors: Hiromitsu SAKAUE, Yamanashi (JP); Toru YAMAUCHI, Yamanashi (JP); Shinji AIZAWA, Yamanashi (JP); Yoshinobu WATANABE, Yamanashi (JP)

(21) Appl. No.: 18/683,478

(22) PCT Filed: Jun. 28, 2022
(86) PCT No.: PCT/JP2022/025652

§ 371 Date: Feb. 13, 2024

(30) Foreign Application Priority Data
Aug. 26, 2021 (JP) 2021-138130

(51) Int. Cl. H01L 21/68; B25J 9/16; G06T 7/73

(52) U.S. Cl. CPC H01L 21/681; B25J 9/1697; G06T 7/73; G06T 2207/30148

(57) ABSTRACT

A jig substrate (200) is used in a teaching method for conveyance mechanisms (12a, 12b, 150) and comprises first cameras (202) and second cameras (204). The first cameras (202) capture first image data for detecting the positions of forks (120, 151) of the conveyance mechanisms (12a, 12b, 150). The second cameras (204) capture second image data for detecting the positions of tables (130, 140) on which substrates are placed.

### TECHNICAL FIELD

The present disclosure relates to a jig substrate and a teaching method.

### BACKGROUND

In the case of manufacturing semiconductor devices, a substrate processing system including a transfer mechanism for transferring a substrate between a plurality of modules is used. In the substrate processing system, a transfer mechanism loads a substrate into each module, and delivers/receives the substrate to/from a placing table disposed in each module. In such a substrate processing system, an operator teaches transfer information such as a substrate placing position in each module or the like to the transfer mechanism using an inspection substrate in order to accurately transfer a substrate into each module. Further, it is suggested to obtain an image of the placing table with a camera disposed at the inspection substrate and correct a position where the substrate is delivered to and received from the placing table by the transfer mechanism based on the obtained image.

### PRIOR ART DOCUMENTS

### Patent Documents

Patent Document 1: Japanese Laid-open Patent Publication No. 2019-102728

### SUMMARY

### Problems to Be Resolved by the Invention

The present disclosure provides a jig substrate and a teaching method capable of improving the accuracy of the transfer position including the height direction.

### Means for Solving the Problems

A jig substrate in accordance with one aspect of the present disclosure, which is used in a teaching method for a transfer mechanism, includes a first camera and a second camera. The first camera captures first image data for detecting a position of a fork of the transfer mechanism. The second camera captures second image data for detecting a position of a placing table on which a substrate is placed.

### Effect of the Invention

In accordance with the present disclosure, the accuracy of the transfer position including the height direction can be improved.

### BRIEF DESCRIPTION OF THE DRAWINGS

FIG. 1 is a horizontal cross-sectional view showing an example of a substrate processing system according to an embodiment of the present disclosure.

FIG. 2 shows an example of a configuration of the substrate processing system according to the embodiment of the present disclosure during teaching.

FIG. 3 shows an example of a jig wafer in the present embodiment.

FIG. 4 shows an example of a camera placing position on a jig wafer.

FIG. 5 is a partial cross-sectional view showing an example of a cross section of the jig wafer near a camera.

FIG. 6 is a cross-sectional view showing an example of detection of the center of a fork.

FIG. 7 is a top view showing an example of the detection of the center of the fork.

FIG. 8 shows an example of relationship between a first camera and the fork.

FIG. 9 shows an example of the orientation of a prism and a captured image.

FIG. 10 shows an example of a graph for determining the Z-axis height from the captured image.

FIG. 11 is a cross-sectional view showing an example of detection of the center of a placing table.

FIG. 12 is a top view showing an example of the detection of the center of the placing table.

FIG. 13 shows an example of relationship between a second camera and marks.

FIG. 14 shows an example of coordinate calculation in FIG. 13.

FIG. 15 shows an example of relationship between the second camera and edge.

FIG. 16 shows an example of coordinate calculation in FIG. 15.

FIG. 17 is a flowchart showing an example of a teaching process in the present embodiment.

FIG. 18 is a flowchart showing an example of a teaching process of an EFEM robot.

FIG. 19 is a flowchart showing an example of an aligner primary teaching process.

FIG. 20 shows an example of a cross section of an aligner and an MTB.

FIG. 21 shows an example of movement of the fork in the aligner primary teaching process.

FIG. 22 shows an example of search mapping.

FIG. 23 shows an example of the search mapping.

FIG. 24 shows an example of the search mapping.

FIG. 25 is a flowchart showing an example of an LP teaching process.

FIG. 26 shows an example of temporary determination of a Z position of a FOUP with respect to a slot.

FIG. 27 shows an example of imaging using a jig wafer in the slot.

FIG. 28 shows an example of positional relationship between the jig wafer and the fork in FIG. 27.

FIG. 29 is a flowchart showing an example of an aligner secondary teaching process.

FIG. 30 shows an example of a state in which the jig wafer is placed on an aligner.

FIG. 31 shows an example of imaging using the jig wafer placed on the aligner.

FIG. 32 shows an example of positional relationship between the jig wafer and the fork in FIG. 31.

FIG. 33 is a flowchart showing an example of an MTB teaching process.

FIG. 34 is a flowchart showing an example of an LLM teaching process of the EFEM robot.

FIG. 35 is a flowchart showing an example of the LLM teaching process of the EFEM robot.

FIG. 36 shows an example of search mapping for a dog of an LLM.

FIG. 37 shows an example of imaging using a jig wafer disposed above the placing table of the LLM.

FIG. 38 shows an example of positional relationship between the jig wafer and the placing table in FIG. 37.

FIG. 39 shows an example of a state in which the jig wafer is placed on lift pins.

FIG. 40 shows an example of imaging using the jig wafer on the lift pins.

FIG. 41 shows an example of positional relationship between the jig wafer and the fork in FIG. 40.

FIG. 42 is a flowchart showing an example of a teaching process of a vacuum transfer robot #1.

FIG. 43 is a flowchart showing an example of an LLM teaching process of the vacuum transfer robot #1.

FIG. 44 is a flowchart showing an example of a PM teaching process.

FIG. 45 is a flowchart showing an example of the PM teaching process.

FIG. 46 shows an example of imaging using the jig wafer disposed above the placing table of the PM.

FIG. 47 shows an example of positional relationship between the jig wafer and the placing table in FIG. 46.

FIG. 48 shows an example of imaging using the jig wafer on lift pins.

FIG. 49 shows an example of positional relationship between the jig wafer and the placing table in FIG. 48.

FIG. 50 is a flowchart illustrating an example of a path teaching process.

FIG. 51 shows an example of a state in which the jig wafer is placed on the path.

FIG. 52 shows an example of imaging using the jig wafer placed on the path.

FIG. 53 shows an example of positional relationship between the jig wafer and the fork in FIG. 52.

FIG. 54 is a flowchart showing an example of a teaching process of vacuum transfer robot #2.

FIG. 55 shows an example of a jig wafer and a captured image in a modification.

### DETAILED DESCRIPTION

Hereinafter, embodiments of a jig substrate and a teaching method of the present disclosure will be described in detail based on the accompanying drawings. Further, the following embodiments are not intended to limit the present disclosure.

Recently, in order to improve performance of processing, it is required to improve transfer accuracy of a device in a substrate processing system. It is known that teaching is performed on the transfer mechanism in order to improve the transfer accuracy. However, in a method for performing teaching of a transfer mechanism by exposing the inside of a device to the atmosphere and manually placing a reference substrate (hereinafter, also referred to as “wafer”) on a placing table, the time for supplying and exhausting air and the time for performing cleaning are required, which results in an increase in downtime. On the other hand, as described above, it is suggested to transfer an inspection substrate provided with a sensor such as a camera or the like in a vacuum state without human intervention, and correct a transfer position where the substrate is delivered to and received from the placing table by the transfer mechanism. However, in the case of the inspection substrate, it is difficult to correct the position of the fork in the height direction. Further, it is difficult to check that the inspection substrate is stationary at the time of capturing an image. Therefore, it is expected to improve the accuracy of the transfer position including the height direction while checking that the inspection substrate (jig substrate) is stationary.

### [Configuration of Substrate Processing System 1]

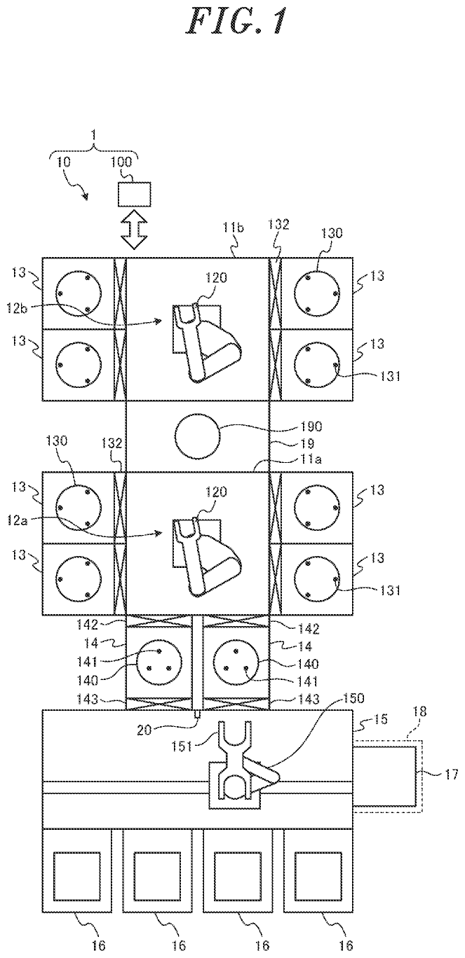

FIG. 1 is a horizontal cross-sectional view showing an example of a substrate processing system according to an embodiment of the present disclosure. A substrate processing system 1 shown in FIG. 1 can perform various treatments such as plasma processing and the like on each wafer (e.g., a semiconductor wafer).

The substrate processing system 1 includes a processing system body 10 and a controller 100 for controlling the processing system body 10. As shown in FIG. 1, for example, the processing system body 10 includes vacuum transfer chambers 11a and 11b, a plurality of process modules 13, a plurality of load-lock modules 14, and an equipment front end module (EFEM) 15. In the following description, the vacuum transfer chambers 11a and 11b are also referred to as VTMs (Vacuum Transfer Modules) 11a and 11b, the process modules 13 are also referred to as PMs (Process Modules) 13, and the load-lock modules 14 are also referred to as LLMs (Load Lock Modules) 14.

Each of the VTMs 11a and 11b has a substantially quadrangular shape in plan view. The plurality of PMs 13 are connected to two opposite side surfaces of each of the VTMs 11a and 11b. Further, the LLMs 14 are connected to one of the other two opposite side surfaces of the VTM 11a, and a path 19 to connect with the VTM 11b is connected to the other of the two opposite side surfaces. The VTM 11b is connected to the VTM 11a through the path 19. The VTMs 11a and 11b have vacuum chambers where robot arms 12a and 12b are disposed, respectively.

The robot arms 12a and 12b are configured to be rotatable, extensible, contractible, and vertically movable. The robot arms 12a and 12b can transfer wafers between the PMs 13, the LLMs 14, and the path 19 while holding the wafers on forks 120 disposed at the tip ends thereof. The robot arms 12a and 12b are examples of a transfer mechanism. The robot arms 12a and 12b are not limited to those shown in FIG. 1 as long as they can transfer the wafers between the PM 13, the LLM 14, and the path 19.

Each PM 13 has a processing chamber where a cylindrical placing table 130 is disposed. The placing table 130 is provided with three thin rod-shaped lift pins 131 capable of projecting from the top surface thereof. The lift pins 131, which are arranged on the same circumference in plan view, project from the upper surface of the placing table 130 to support and lift the wafer placed on the placing table 130 and retract into the placing table 130 to place the wafer on the placing table 130. After the wafer is placed on the placing table 130, a pressure in the PM 13 is reduced and a processing gas is introduced. Then, a radio frequency power is applied into the PM 13 to generate plasma, and plasma processing is performed on the wafer by the plasma. The VTMs 11a and 11b and the PM 13 are partitioned by gate valves 132 that can be opened and closed.

The LLMs 14 are disposed between the VTM 11a and the EFEM 15. Each of The LLMs 14 has a chamber of which inner pressure can be switched between a vacuum state and an atmospheric pressure, and a cylindrical placing table 140 disposed therein. In the case of loading the wafer from the EFEM 15 into the VTM 11a, the wafer is transferred from the EFEM 15 into the LLM 14 maintained at an atmospheric pressure; the pressure in the LLM 14 is decreased; and the wafer is loaded into the VTM 11a. In the case of unloading the wafer from the VTM 11a into the EFEM 15, the wafer is transferred from the VTM 11a into the EFEM 15 maintained in a vacuum state; the pressures in the LLM 14 is increased to an atmospheric pressure; and the wafer is loaded into the EFEM 15. The placing table 140 is provided with three thin rod-shaped lift pins 141 capable of projecting from the top surface thereof. The lift pins 141, which are arranged on the same circumference in plan view, project from the upper surface of the placing table 140 to support and lift the wafer and retract into the placing table 140 to place the supported wafer on the placing table 140. The LLMs 14 and the VTM 11a are partitioned by gate valves 142 that can be opened and closed. Further, the LLMs 14 and the EFEM 15 are partitioned by gate valves 143 that can be opened and closed. Further, a dog 20 is disposed between two LLMs 14 to determine the heights (Z-axis) of the LLMs 14. The dog 20 is detected by mapping sensors 151a disposed at the tip ends of the fork 151, which will be described later, in a state where the gate valves 143 of the two LLMs 14 are opened. The mapping sensors 151a are, for example, light blocking sensors disposed to face the inner sides of the tip ends of the teeth on both sides of the fork 151.

The EFEM 15 is disposed to be opposite to the VTM 11a. The EFEM 15 is a rectangular parallelepiped-shaped atmospheric transfer chamber having a fan filter unit (FFU), and maintained at an atmospheric pressure. The two LLMs 14 are connected to one long side of the EFEM 15. Four load ports (LP) 16 are connected to the other long side of the EFEM 15. A front opening unified pod (FOUP) (not shown), which is a container accommodating a plurality of wafers, is placed on each LP 16. An aligner 17 and a mapping temporary buffer (MTB) 18 are connected to one short side of the EFEM 15. Further, a robot arm 150 is disposed in the EFEM 15.

The robot arm 150 is configured to be movable along a guide rail, and is configured to be rotatable, extensible, contractible, and vertically movable. The robot arm 150 can transfer the wafer between the FOUP of the LP 16, the aligner 17, the MTB 18, and the LLM 14 while holding the wafer on a fork 151 disposed at the tip end thereof. The robot arm 150 is an example of a transfer mechanism. The robot arm 150 is not limited to that shown in FIG. 1 as long as it can transfer the wafer between the FOUP, the aligner 17, the MTB 18, and the LLM 14.

The aligner 17 aligns the wafer. The aligner 17 has a rotation stage (not shown) rotated by a driving motor (not shown). The rotation stage has a diameter smaller than that of the wafer, for example, and is configured to be rotatable while holding the wafer on the upper surface thereof. An optical sensor for detecting the peripheral edge of the wafer is disposed near the rotation stage. In the aligner 17, the optical sensor detects the center position of the wafer and the direction of the notch with respect to the center of the wafer, and the wafer is delivered to and received from the fork 151 such that the center position of the wafer and the direction of the notch become a predetermined position and a predetermined direction. Accordingly, the transfer position of the wafer is adjusted such that the center position of the wafer and the direction of the notch become a predetermined position and a predetermined direction in the LLM 14. Further, the MTB 18 is disposed directly below the aligner 17, so that the wafer can temporarily retract.

The path 19 is disposed between the VTM 11a and the VTM 11b. The path 19 includes a path stage 190 for transferring the wafer between the VTM 11a and the VTM 11b. The path stage 190 has a diameter smaller than the diameter of the wafer and the gap between the teeth of the fork 120.

The substrate processing system 1 includes the controller 100. The controller 100 is, for example, a computer, and includes a central processing unit (CPU), a random access memory (RAM), a read only memory (ROM), an auxiliary storage device, and the like. The CPU operates based on a program stored in the ROM or the auxiliary storage device, and controls operations of individual components of the substrate processing system 1.

### [Configuration of Substrate Processing System 1 During Teaching]

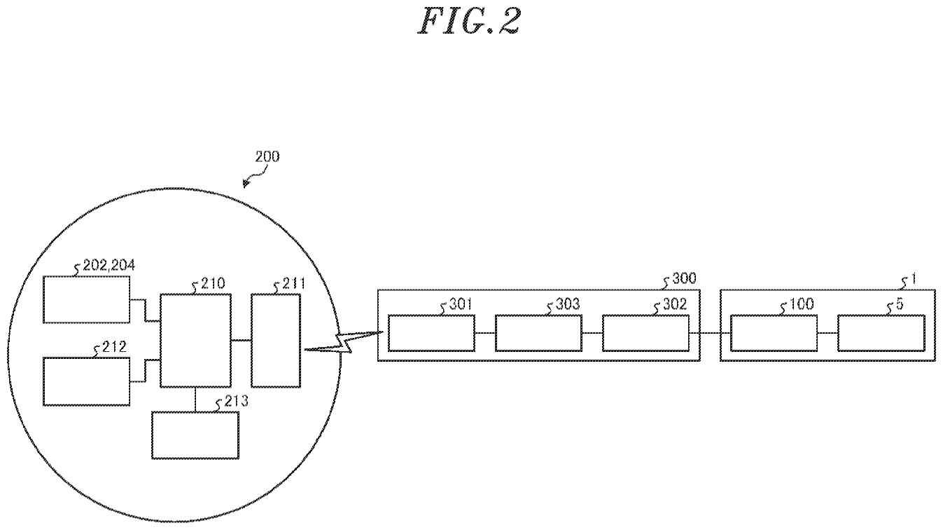

FIG. 2 shows an example of a configuration of a substrate processing system according to an embodiment of the present disclosure during teaching. As shown in FIG. 2, in the case of teaching the transfer mechanism of the substrate processing system 1, a jig wafer 200 and an information processor 300 are connected to the controller 100 of the substrate processing system 1.

During the teaching, the controller 100 instructs the information processor 300 to perform teaching for an arbitrary position. Further, the controller 100 obtains information on the wafer placing position and the touch position of the fork from the information processor 300, and reflects the information in the transfer position data for controlling a robot controller 5. The robot controller 5 is a controller for controlling the robot arms 12a, 12b, and 150.

The jig wafer 200, which is a teaching jig for a transfer mechanism, is transferred into each module, captures images of the placing table and the fork, and transmits the images to the information processor 300. The jig wafer 200 includes a first camera 202, a second camera 204, a controller 210, a communication part 211, a motion sensor 212, and a battery 213. The motion sensor 212 includes a gyro sensor and an acceleration sensor.

Each of the first camera 202 and the second camera 204 includes a plurality of cameras, and captures images of the fork and the placing table. The controller 210 obtains the images captured by the first camera 202 and the second camera 204 based on the instruction received from the information processor 300 via the communication part 211. Further, the controller 210 obtains angular velocity data or acceleration data using the motion sensor 212 based on the received instruction. The controller 210 transmits the captured image, the angular velocity data, the acceleration data, or the like to the information processor 300 via the communication part 211. The communication part 211 is a wireless communication module, and may be a module such as Bluetooth (Registered Trademark) or Wi-Fi (Registered Trademark), for example. The motion sensor 212 measures the angular velocity of the jig wafer 200, and outputs the measurement data to the controller 210. The battery 213 supplies a power to each part of the jig wafer 200. A lithium ion secondary battery or a lithium ion polymer secondary battery may be used as the battery 213, for example.

The information processor 300 is, e.g., a personal computer, and uses the jig wafer 200 to acquire various data and perform calculation or the like based on the teaching instruction received from the controller 100. The information processor 300 includes a first communication part 301, a second communication part 302, and a controller 303. The first communication part 301 is a wireless communication module, and may be a module such as Bluetooth (Registered Trademark) or Wi-Fi (Registered Trademark), for example. The first communication part 301 communicates with the communication part 211 of the jig wafer 200. The second communication part 302 is, for example, a network interface card (NIC), and communicates with the controller 100 in a wired or wireless manner.

The controller 303 includes a CPU, an RAM, an ROM, an auxiliary storage device, and the like. The CPU operates based on a program stored in the ROM or the auxiliary storage device, and performs information processing such as teaching in the information processor 300. When the teaching instruction is received from the controller 100, the controller 303 performs various processes such as data acquisition for the jig wafer 200, image processing based on the obtained data, position calculation, and the like. Further, the controller 303 stores logs such as the captured images and the measurement data in a storage part (not shown). The information processor 300 may be built in the substrate processing system 1, or the controller 100 may execute various processes in the information processor 300.

### [Jig Wafer]

Next, the jig wafer 200 will be described. In the following description, the coordinates set with respect to the modules such as the VTMs 11a and 11b, the PMs 13, the LLMs 14, and the EFEM 15 are indicated by the XYZ-axes, and the coordinates set with respect to the jig wafer 200 are indicated by the XY-axes.

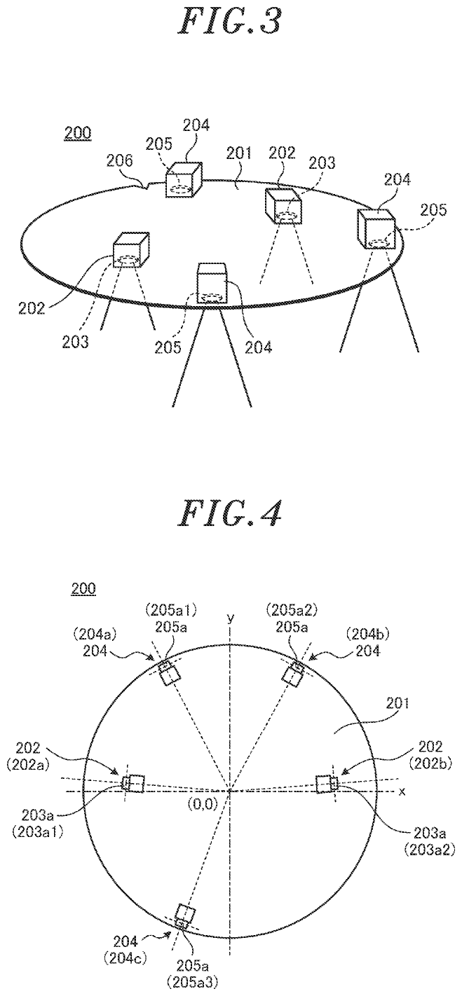

FIG. 3 shows an example of a jig wafer in the present embodiment. As shown in FIG. 3, the cameras of the jig wafer 200 include a plurality of (for example, two) first cameras 202 and a plurality of (for example, three) second cameras 204 on a base wafer 201. The base wafer 201 is preferably a wafer having the same size as that of a product wafer. Since the wafer having the same size as that of the product wafer is used as the base wafer 201, the jig wafer 200 can be transferred between multiple modules, similarly to the product wafer. Specifically, in the case of using a product wafer having a diameter of 300 mm, for example, it is preferable to use a wafer having a diameter of 300 mm as the base wafer 201. Although it is not shown in FIG. 3, the jig wafer 200 also includes the above-described motion sensor 212.

The first cameras 202 are arranged, for example, on the same circumference of the base wafer 201 to be located at positions to be in contact with the fork. For example, it is preferable to provide the first cameras 202 at two locations on the same circumference on the XY-axes with respect to the center of the base wafer 201. Each of the first cameras 202 is configured to image the lower side of the base wafer 201 through a prism 203a and an opening 203 formed in the base wafer 201, which will be described later.

The second cameras 204 are arranged on the same circumference to be located at the peripheral edge of the surface of the base wafer 201, for example. For example, it is preferable to provide the second cameras 204 at three locations on the same circumference on the XY-axes with respect to the center of the base wafer 201. Each of the second cameras 204 is configured to image the lower side of the base wafer 201 through a prism 205a and an opening 205 formed in the base wafer 201, which will be described later.

Next, the placing positions of the first cameras 202 and the second cameras 204 will be described in detail with reference to FIG. 4. FIG. 4 shows an example of a camera placing position on a jig wafer. As shown in FIG. 4, the first cameras 202 include a first camera 202a disposed near the negative side of the X-axis of the base wafer 201, and a first camera 202b disposed near the positive side of the X-axis of the base wafer 201. The second cameras 204 include a second camera 204a disposed in the second quadrant, a second camera 204b disposed in the first quadrant, and a second camera 204c disposed in the third quadrant of the XY coordinates of the base wafer 201.

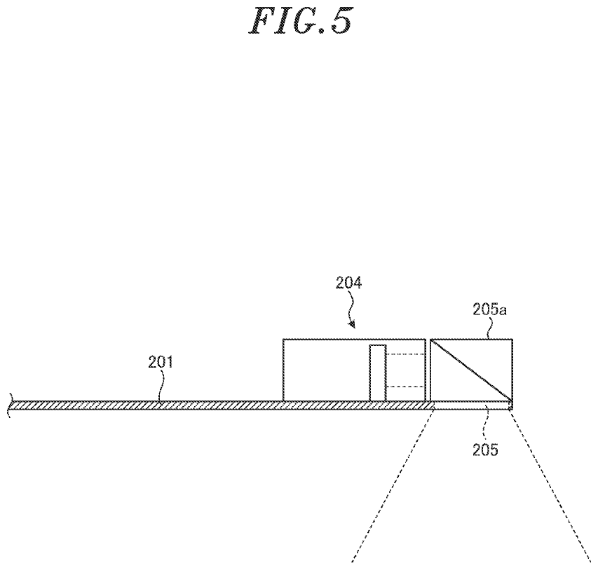

FIG. 5 is a partial cross-sectional view showing an example of a cross section of the jig wafer near the camera. As shown in FIG. 5, the second camera 204 is installed such that an optical axis becomes parallel to the base wafer 201, and is configured to capture the lower side of the jig wafer 200 through the prism 205a and the opening 205. Since the prism 205a is used, the thickness of the jig wafer 200 can be reduced. The first camera 202 and the prism 203a are installed in the same manner. Although not shown, light emitting diodes (LED) for illumination are disposed near the prisms 203a and 205a.

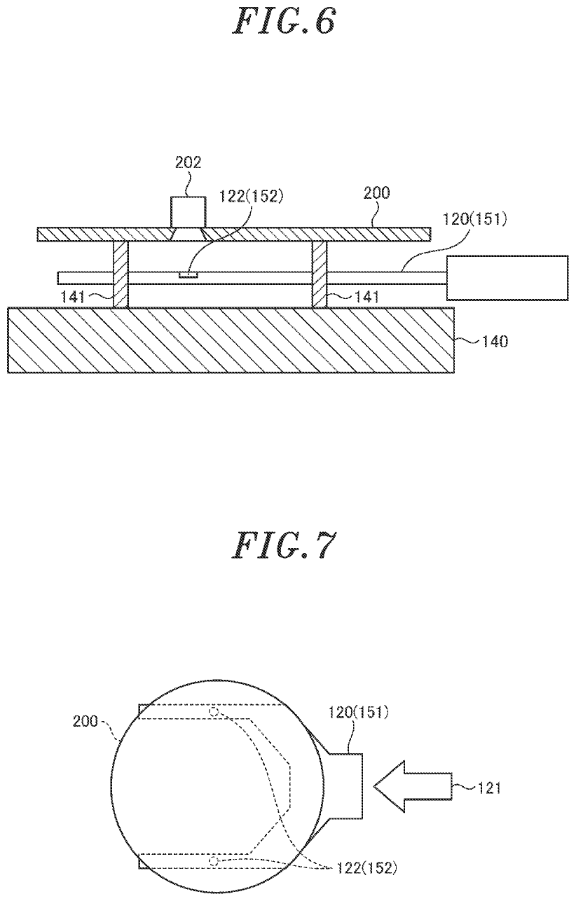

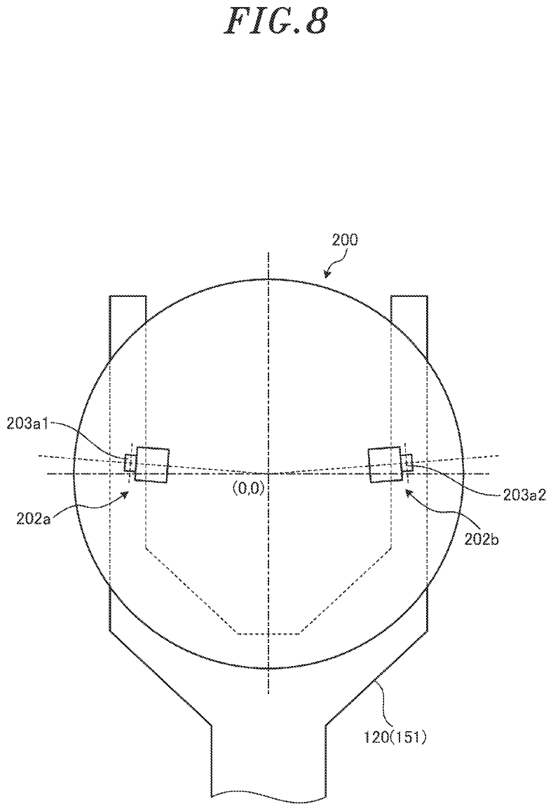

Next, the detection of the center of the fork will be described with reference to FIGS. 6 to 10. FIG. 6 is a cross-sectional view showing an example of detection of the center of the fork. FIG. 7 is a top view showing an example of detection of the center of the fork. As shown in FIGS. 6 and 7, for example, in a state where the jig wafer 200 is placed on the lift pins 141 on the placing table 140 of the LLM 14, the fork 120 or the fork 151 is moved to a touch potion between the placing table 140 and the jig wafer 200 as indicated by an arrow 121. The first camera 202 captures marks 122 or marks 152 serving as position detection targets disposed at the teeth of the fork 120 or the fork 151 through the prism 203a and the opening 203. The marks 122 and 152 may be marks using a phosphorescent material for use in dark places.

FIG. 8 shows an example of the relationship between the first camera and the fork. As shown in FIGS. 7 and 8, at the left teeth of the fork 120 or the fork 151, the mark 122 or the mark 152 disposed at the left teeth of the fork 120 or the fork 151 is captured by the first camera 202a through the prism 203a1. Further, at the right teeth, the mark 122 or the mark 152 disposed at the right teeth is captured by the first camera 202b through a prism 203a2. Next, the Z-axis coordinate detection will be described using the first camera 202b as an example.

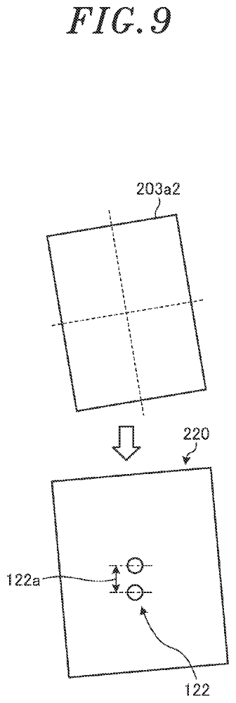

FIG. 9 shows an example of the orientation of a prism and a captured image. As shown in FIG. 9, the prism 203a2 is rotated from the X-axis of the jig wafer 200, so that the captured image 220 is also rotated. In the captured image 220, the mark 122 is captured, and two circular points of the mark 122 are included. The information processor 300 performs circular edge detection to calculate an inter-point distance 122a between the center coordinates of the two points. The inter-point distance in the mark 152 can be calculated in the same manner.

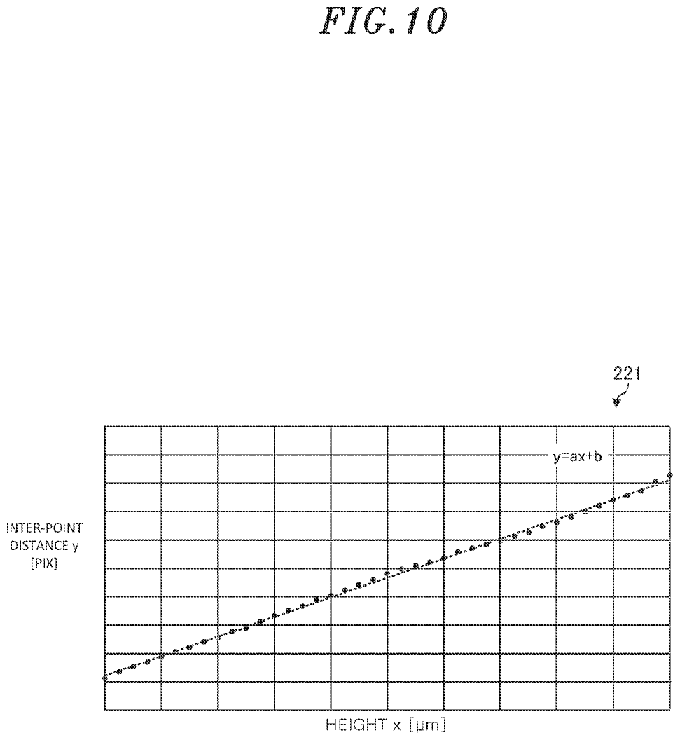

FIG. 10 shows an example of a graph for determining the Z-axis height from a captured image. The information processor 300 calculates the heights of the forks 120 and 151, i.e., the Z-axis coordinates, based on the equation obtained from a graph 221 in which the pre-measured inter-point distance and the heights from the forks 120 and 151 to the jig wafer 200 shown in FIG. 10 are correlated. The information processor 300 calculates a touch position value indicating the distance to the touch position based on the calculated Z-axis coordinate and the target value of the touch position. The information processor 300 can obtain the values of the three axes at the touch positions of the forks 120 and 151 based on the XY-axes deviation amount from the center of the placing table, which will be described later, and the touch position value.

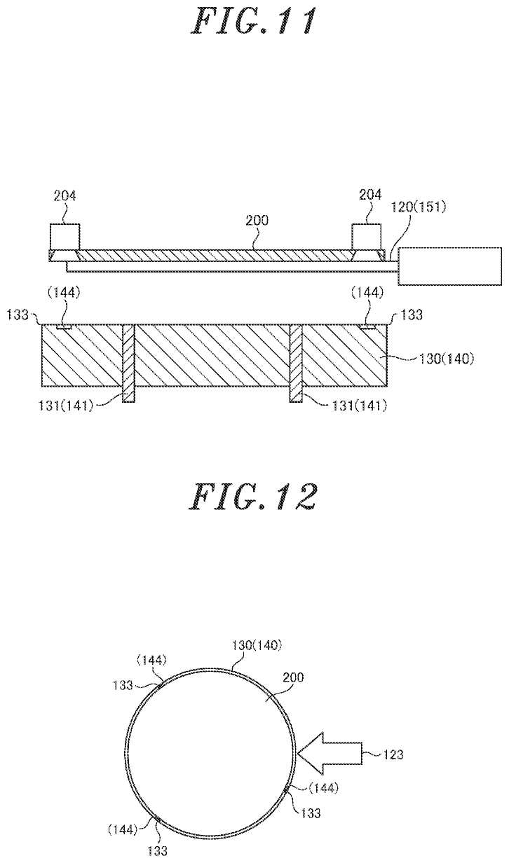

Next, the detection of the center of the placing table will be described with reference to FIGS. 11 to 16. FIG. 11 is a cross-sectional view showing an example of detection of the center of the placing table. FIG. 12 is a top view showing an example of detection of the center of the placing table. As shown in FIGS. 11 and 12, for example, in the PM 13 or the LLM 14, as indicated by an arrow 123, the fork 120 or the fork 151 on which the jig wafer 200 is placed is moved to a position above the placing table 130 or the placing table 140, respectively. The second camera 204 captures edges 133 of the placing table 130 or the placing table 140, or marks 144 serving as position detection targets through the prism 205a and the opening 205.

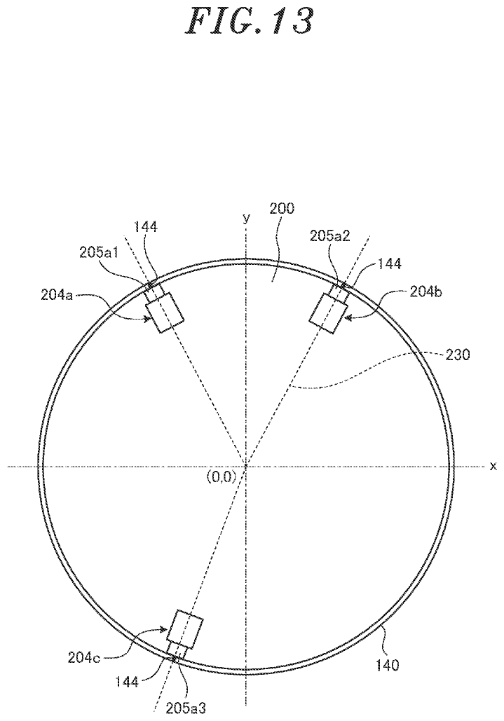

FIG. 13 shows an example of the relationship between the second camera and the marks. As shown in FIG. 13, in the placing table 140, the marks 144 disposed at the peripheral edge of the placing table 140 are captured by the second cameras 204a to 204c through prisms 205a1 to 205a3, respectively. In the case of the second camera 204b, for example, an optical axis 230 of the second camera 204b overlaps a straight line passing through the reference coordinates (0, 0) of the jig wafer 200. In other words, the XY-axes of the captured image and the XY-axes of the jig wafer 200 are different.

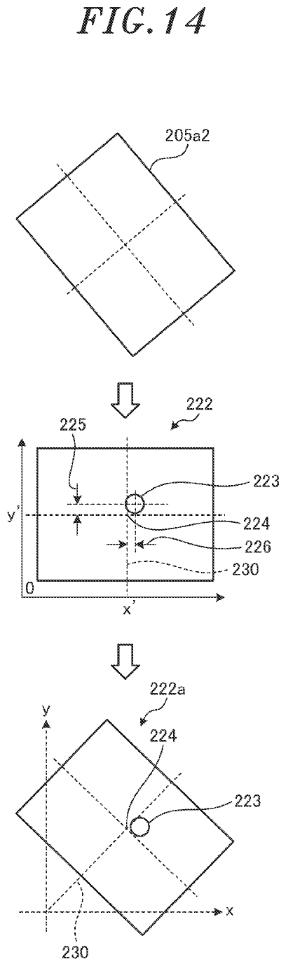

FIG. 14 shows an example of coordinate calculation in FIG. 13. In FIG. 14, the jig wafer 200 is placed on the normal position of the fork 151. As shown in FIG. 14, although the prism 205a2 is rotated from the X-axis of the jig wafer 200, the captured image 122 is an image in which the optical axis 230 is aligned with the y′-axis. In the captured image 222, an opening 223 that is an example of the mark 144 is captured. The mark 144 may be a mark using a phosphorescent material for use in dark places. The information processor 300 performs circular edge detection to calculate the center coordinates of the opening 223 in the captured image 222. Here, the imaging range of the captured image 222 is calibrated in advance for each jig wafer 200, and it is considered that the jig wafer 200 has been calibrated to be located at the center of the placing table 140 when center coordinates 224 of the captured image 222 coincide with the center coordinates of the opening 223. Therefore, the information processor 300 can calculate the XY-axes deviation amounts of the fork 151 on the placing table 140 by calculating differences 225 and 226 between the center coordinates of the opening 223 and the center coordinates 224 of the captured image 222.

The information processor 300 rotates the captured image 222 such that the optical axis 230 is aligned with the coordinates of the XY-axes of the jig wafer 200 to generate a captured image 222a in which the x′y′-axes of the captured image 222 are aligned with the xy-axes of the jig wafer 200. In other words, the information processor 300 converts the center coordinates of the opening 223 and the center coordinates 224 of the captured image 222 to the coordinates of the xy-axes of the jig wafer 200. Similarly, the information processor 300 obtains the central coordinates of the opening 223 and the center coordinates 224 on the xy-axes of the jig wafer 200 from the images captured by the second cameras 204a and 204c. The information processor 300 calculates the XY values of the center coordinates of the placing table 140 based on the center coordinates of the opening 223 at three locations, and calculates the current XY values of the center coordinates of the jig wafer 200 based on the converted coordinates corresponding to the differences 225 and 226 at the three locations. The information processor 300 calculates the XY-axes deviation amount of the fork 151 based on the XY values of the center coordinates of the placing table 140 and the current XY values of the center coordinates of the jig wafer 200.

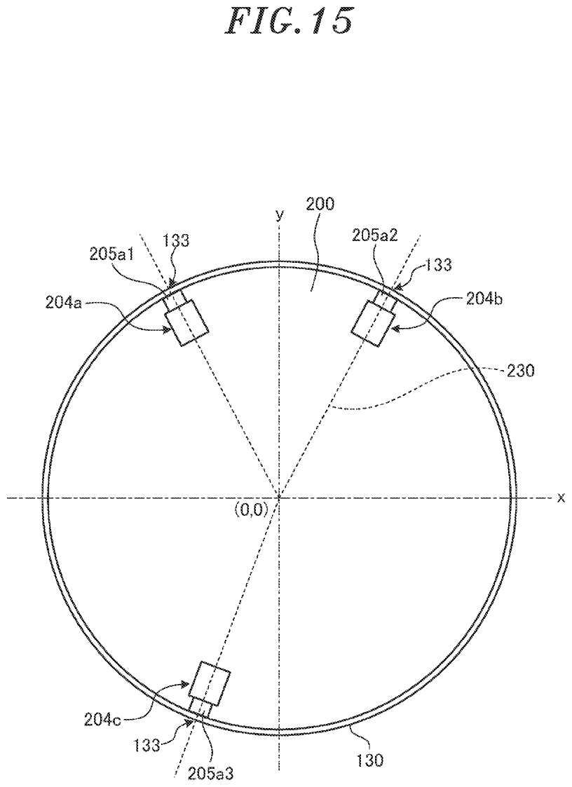

FIG. 15 shows an example of the relationship between the second camera and the edge. As shown in FIG. 15, in the placing table 130, the edge 133 of the peripheral portion of the placing table 130 is captured by the second cameras 204a to 204c through the prisms 205a1 to 205a3, respectively. In the case of the second camera 204b, for example, the optical axis 230 of the second camera 204b overlaps a straight line passing through the reference coordinates (0, 0) of the jig wafer 200. In other words, the xy-axes of the captured image and the xy-axes of the jig wafer 200 are different.

FIG. 16 shows an example of coordinate calculation in FIG. 15. As shown in FIG. 16, although the prism 205a2 is rotated from the x-axis of the jig wafer 200, the captured image 231 is an image in which the optical axis 230 is aligned with the y′ axis. In the captured image 231, an edge 232 that is an example of the edge 133 is captured. In the captured image 231, the edge 232 located at the center through which the optical axis 230 passes is indicated by a circle. The information processor 300 performs edge detection to detect the coordinates of the edge 232 in the captured image 231. Here, the imaging range of the captured image 231 is calibrated in advance for each jig wafer 200, and it is considered that the jig wafer 200 has been calibrated to be located at the center of the placing table 130 when the center coordinates 233 of the captured image 231 coincide with the value of the y′-axis of the edge 232. Therefore, the information processor 300 can calculate the XY-axis deviation amount of the fork 120 on the placing table 130 by calculating a difference 234 between the y′-axis value of the edge 232 and the y′-axis value of the center coordinates 233 of the captured image 231.

The information processor 300 rotates the captured image 231 such that the optical axis 230 is aligned with the coordinates of the xy-axes of the jig wafer 200 to generate a captured image 231a in which the x′y′-axes of the captured image 231 are aligned with the xy-axes of the jig wafer 200. In other words, the information processor 300 converts the coordinates of the edge 232 and the center coordinates 233 of the captured image 231 to the coordinates of the xy-axes of the jig wafer 200. Similarly, the information processor 300 obtains the coordinates of the edge 232 and the center coordinates 233 on the xy-axes of the jig wafer 200 from the captures captured by the second cameras 204a and 204c. The information processor 300 calculates the XY values of the center coordinates of the placing table 130 based on the coordinates of the edge 232 at three locations, and calculates the current XY values of the center coordinates of the jig wafer 200 based on the changed coordinates corresponding to the differences 234 at the three locations. The information processor 300 calculates the XY-axes deviation amount of the fork 120 the based on the XY values of the center coordinates of the placing table 130 and the current XY values of the center coordinates of the jig wafer 200.

### [Teaching Method]

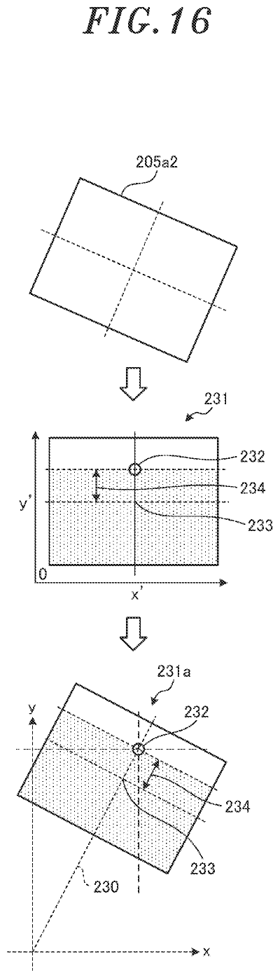

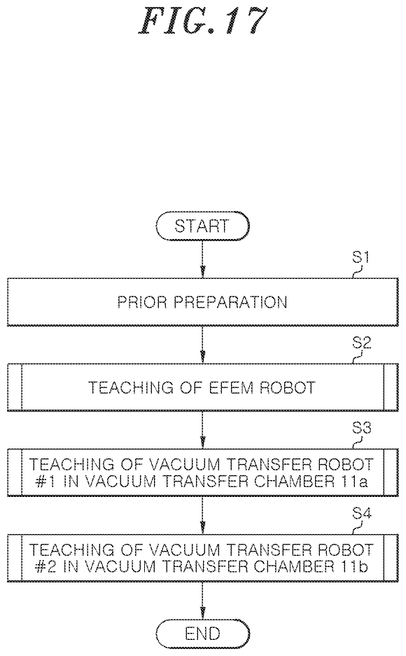

Next, the operation of the substrate processing system 1 of the present embodiment during teaching will be described. FIG. 17 is a flowchart showing an example of a teaching process in the present embodiment. In the following description, the operations of individual components of the substrate processing system 1 are controlled by the controller 100, and the teaching is controlled by the information processor 300. Further, the teaching process in the present embodiment is performed in an environment of an atmospheric pressure and room temperature.

First, an operator performs prior preparation such as mechanical adjustment such as horizontal adjustment or height adjustment, setting of a FOUP containing the jig wafer 200, and selection of a teaching location (step S1). In the present embodiment, the case of performing teaching on individual components of the processing system body 10 at once will be described.

When the prior preparation is completed, the information processor 300 performs a teaching process of the EFEM robot (step S2). Here, the teaching process of the EFEM robot will be described with reference to FIG. 18. FIG. 18 is a flowchart showing an example of the teaching process of the EFEM robot.

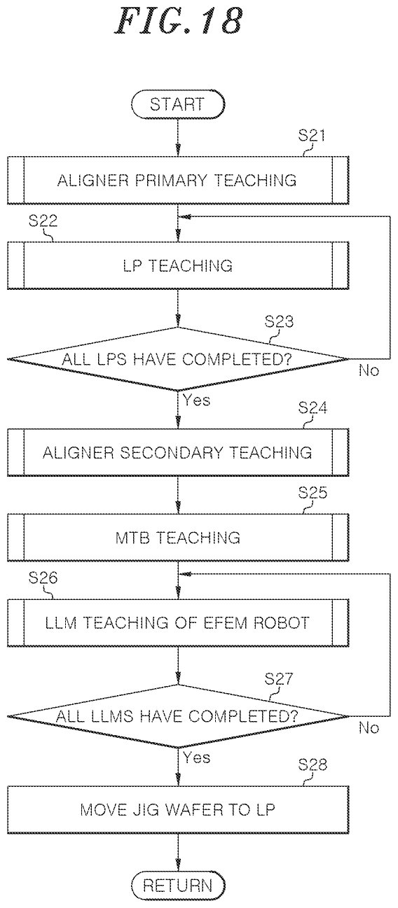

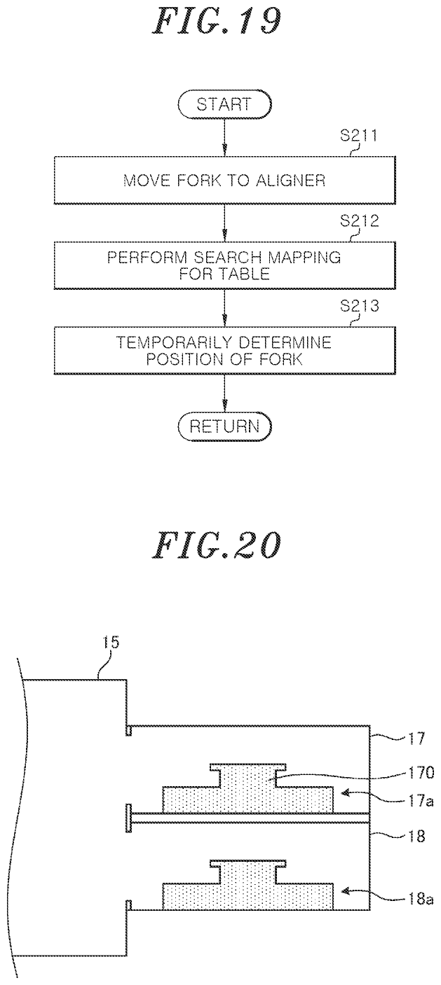

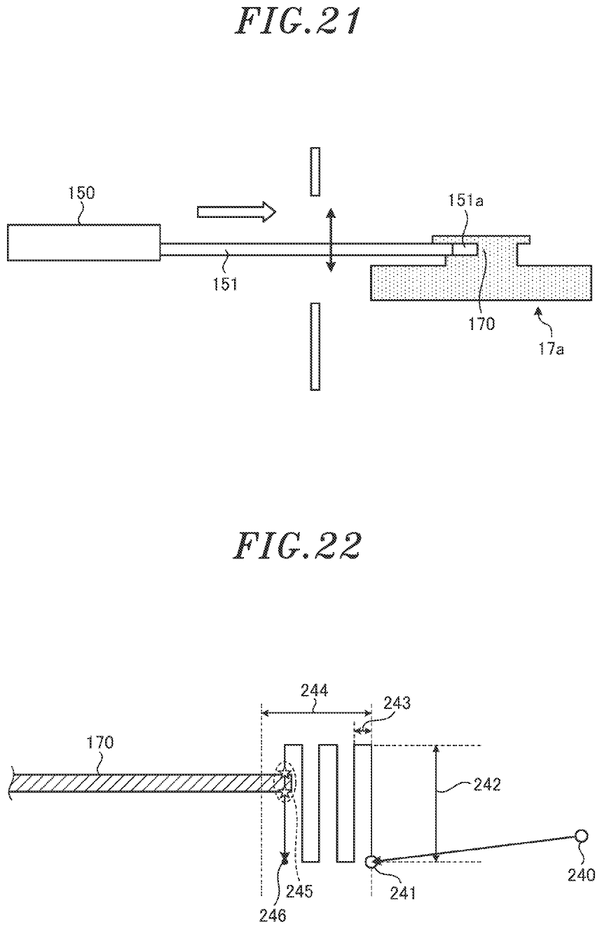

The information processor 300 first performs an aligner primary teaching process (step S21). Here, the aligner primary teaching process will be described with reference to FIG. 19. Further, the movement of the fork 151 viewed in the cross sections of the aligner 17 and the MTB 18 will be described with reference to FIGS. 20 and 21. FIG. 19 is a flowchart showing an example of the aligner primary teaching process. FIG. 20 shows an example of the cross section of the aligner and the MTB. FIG. 21 shows an example of the movement of the fork in the aligner primary teaching process.

The information processor 300 instructs, via the controller 100, the robot arm 150 to move the fork 151 to the aligner 17 (step S211). As shown in FIG. 20, the aligner 17 has a table 170 on a rotation stage 17a. The MTB 18 is located directly below the aligner, and has a placing table 18a. As shown in FIG. 21, the robot arm 150 moves to the aligner 17, extends the fork 151 to the table 170, and performs search mapping for the table 170 using the mapping sensors 151a disposed at the tip ends of the teeth of the fork 151 (step S212).

FIGS. 22 to 24 show an example of the search mapping. Although FIGS. 22 to 24 show the case of detection of the table 170, the description thereof will be omitted because it is the same as the detection of the jig wafer 200 in the FOUP of the LP 16, the detection of the placing table 18a in the MTB 18, and the detection of the dog 20 in the LLM 14.

As shown in FIG. 22, the robot arm 150 moves the fork 151, and moves the mapping sensors 151a disposed at the tip ends of the teeth to an initial position 240. Next, the robot arm 150 moves the mapping sensor(s) 151a of the fork 151 to a start position 241 of the search operation, and vertically moves by a search width 242 and a width 243 in a forward direction to detect the table 170 with the mapping sensors 151a disposed at the tip ends of the teeth. The search width 242 and the width 243 may be, e.g., 10 mm and 1 mm, respectively. The search operation continues to the end of a search offset 244 in the forward direction. The search offset 244 may be, e.g., 10 mm. When the table 170 is detected at a detection point 245, the robot arm 150 moves the mapping sensors 151a of the fork 151 to a lower position 246 of the vertical movement. When the table 170 is detected during the search operation performed from bottom to top, the robot arm 150 moves the mapping sensor 151a of the fork 151 to an upper position.

As shown in FIG. 23, the robot arm 150 moves the mapping sensor 151a of the fork 151 in the forward direction by the width 243, and then moves the mapping sensor 151a upward to an upper position 249 at a reduced movement speed. The robot arm 150 records a bottom position 247 where a rising edge is detected by the mapping sensor 151a and a top position 248 where a falling edge is detected by the mapping sensor 151a.

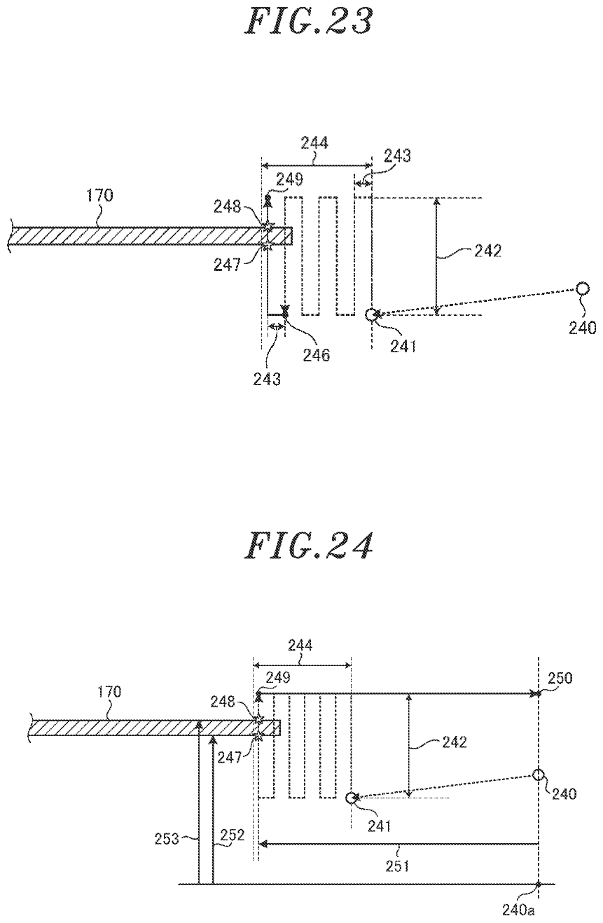

As shown in FIG. 24, the robot arm 150 moves the mapping sensor 151a of the fork 151 from the upper position 249 to a retract position 250 without changing the Z-axis position (height). The robot arm 150 outputs the Z-axis positions of the bottom position 247 and the top position 248 and a movement amount 251 of the fork on the XY-axes to the controller 100. The controller 100 calculates Z-axis driving amounts 252 and 253 of the robot arm 150 from a home position 240a based on the Z-axis positions of the bottom position 247 and the top position 248, and reflects it in the teaching position of the robot arm 150 together with the movement amount 251. The controller 100 transmits the teaching position to the information processor 300. The information processor 300 temporarily determines the position of the fork 151 based on the teaching position (step S213), and returns to the original processing.

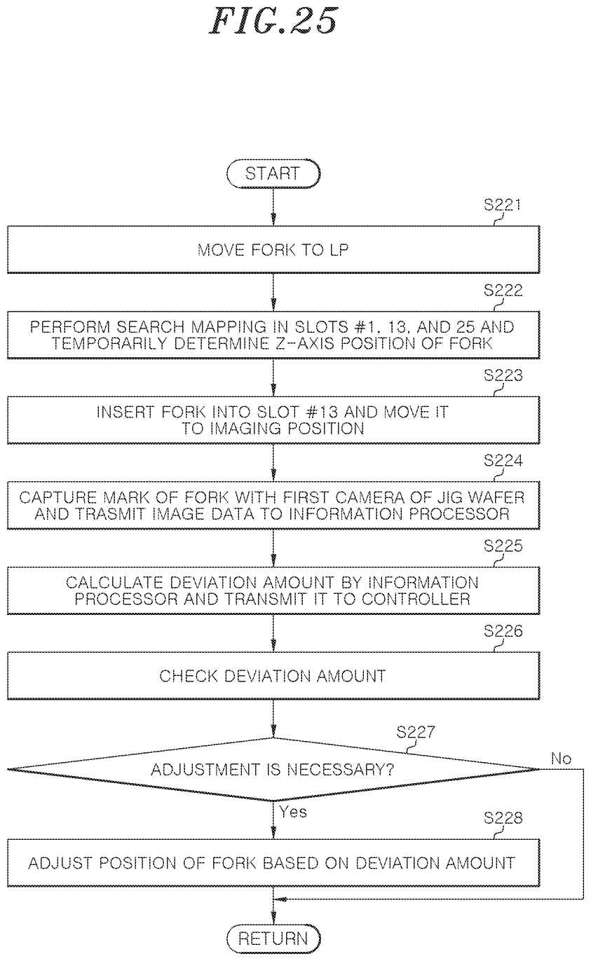

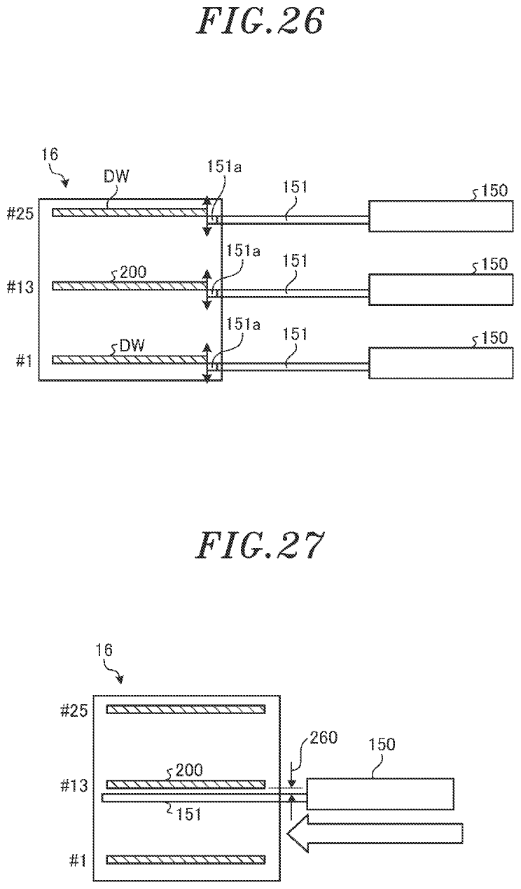

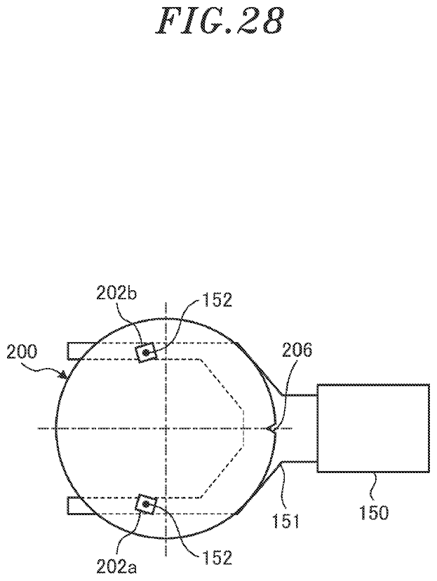

Referring back to the description of FIG. 18, the information processor 300 performs an LP teaching process (step S22). Here, the LP teaching process will be described with reference to FIGS. 25 to 28. FIG. 25 is a flowchart showing an example of the LP teaching process. FIG. 26 shows an example of temporary determination of the Z position with respect to the slot of the FOUP. FIG. 27 shows an example of imaging using the jig wafer in the slot. FIG. 28 shows an example of the positional relationship between the jig wafer and the fork in FIG. 27.

The information processor 300 instructs, via the controller 100, the robot arm 150 to move the fork 151 to the LP 16 (step S221). As shown in FIG. 26, the robot arm 150 performs search mapping on the jig wafer 200 in slot #13 and dummy wafers DW in slots #1 and #25 in the FOUP placed on the LP 16, and temporarily determines the Z-axis position of the fork 151 (step S222).

As shown in FIG. 27, the robot arm 150 inserts the fork 151 into slot #13, and moves it to an imaging position (step S223). In this case, a distance 260 between the jig wafer 200 and the fork 151 is set to a predetermined value.

When the movement of the fork 151 to the imaging position is received from the controller 100, the information processor 300 instructs the jig wafer 200 to perform imaging. As shown in FIG. 28, the jig wafer 200 captures the marks 152 of the fork 151 with the first cameras 202a and 202b. In this case, a notch 206 of the jig wafer 200 is directed to the base side of the fork 151. The jig wafer 200 transmits the captured image data to the information processor 300 (step S224). The information processor 300 calculates the XYZ-axes deviation amount based on the received image data, and transmits it to the controller 100 (step S225).

The controller 100 checks whether or not the received deviation amount is within a preset allowable range (step S226). Then, the controller 100 determines whether or not adjustment is necessary as a result of checking the deviation amount (step S227). When it is determined that the adjustment is necessary (step S227: Yes), the controller 100 adjusts the position of the fork 151 based on the deviation amount (step S228), and returns to the original processing. In other words, the controller 100 corrects the transfer position data of the fork 151 in the slot in the FOUP. On the other hand, when it is determined that the adjustment is not necessary (step S227: No), the controller 100 returns to the original processing without performing the adjustment.

Referring back to the description of FIG. 18, when the LP teaching process is completed, the information processor 300 determines whether or not all the LPs 16 have completed the LP teaching process (step S23). When it is determined that all the LPs 16 have not completed the LP teaching process of (step S23: No), the information processor 300 returns to step S22 and performs the LP teaching process for the remaining LPs 16. In this case, an operator may move the FOUP accommodating the jig wafers 200 between the LPs 16, or the FOUP accommodating the jig wafers 200 may be set in all the LPs 16 in advance. When it is determined that all the LPs 16 have completed the LP teaching process (step S23: Yes), the information processor 300 performs the aligner secondary teaching process (step S24).

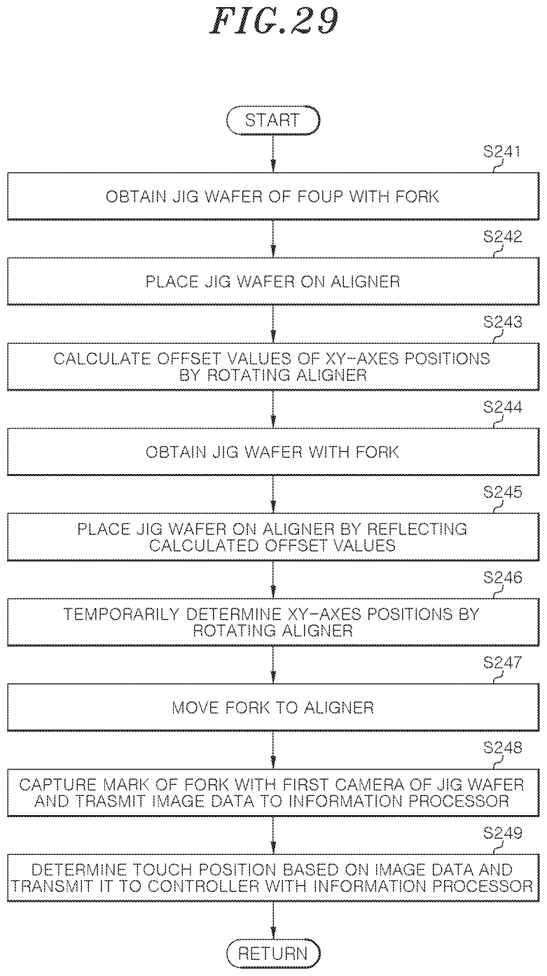

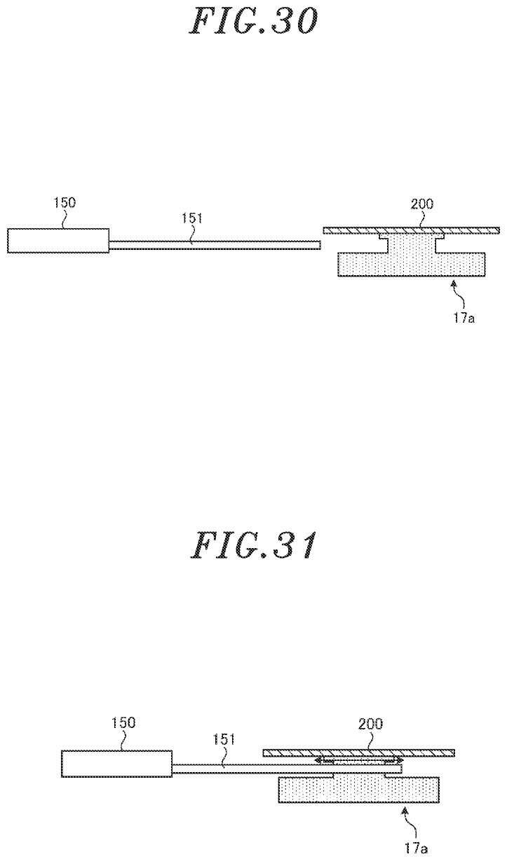

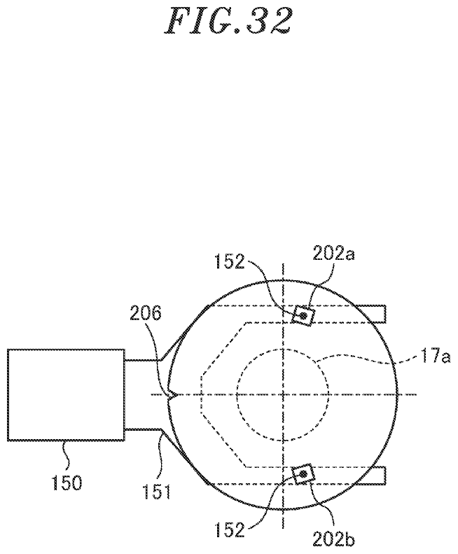

Here, the aligner secondary teaching process will be described with reference to FIGS. 29 to 32. FIG. 29 is a flowchart showing an example of the aligner secondary teaching process. FIG. 30 shows an example of a state in which the jig wafer is placed on the aligner. FIG. 31 shows an example of imaging using the jig wafer placed on the aligner. FIG. 32 shows an example of the positional relationship between the jig wafer and the fork in FIG. 31.

The information processor 300 instructs, via the controller 100, the robot arm 150 to obtain the jig wafer 200 in the FOUP with the fork 151 (step S241). As shown in FIG. 30, the robot arm 150 places the obtained jig wafer 200 on the rotation stage 17a of the aligner 17 (step S242). The controller 100 rotates the rotation stage 17a of the aligner 17, and calculates the offset values of the XY-axes positions based on the amount of eccentricity (step S243).

The robot arm 150 obtains the jig wafer 200 from the rotation stage 17a with the fork 151 (step S244). The controller 100 reflects the calculated offset values, and instructs the robot arm 150 to place the jig wafer 200 on the rotation stage 17a of the aligner 17. The robot arm 150 places the jig wafer 200 on the rotation stage 17a of the aligner 17 based on the instruction (step S245).

The controller 100 rotates the rotation stage 17a of the aligner 17, and temporarily determines the XY-axes positions based on the amount of eccentricity (step S246). The dummy wafer DW such as a bare silicon wafer or the like may be used, instead of the jig wafer 200, to calculate the offset value of the rotation stage 17a and temporarily determine the XY-axes positions. The controller 100 instructs the robot arm 150 to move the fork 151 to the aligner 17. As shown in FIG. 31, the robot arm 150 moves the fork 151 to the imaging position where the marks 152 of the fork 151 can be captured by the first camera 202 of the jig wafer 200 (step S247).

When the movement of the fork 151 to the imaging position is received from the controller 100, the information processor 300 instructs the jig wafer 200 to perform imaging. As shown in FIG. 32, the jig wafer 200 captures the marks 152 of the fork 151 with the first cameras 202a and 202b. In this case, the notch 206 of the jig wafer 200 is directed to the base side of the fork 151. Further, the teeth of the fork 151 and the rotation stage 17a are positioned so as not to interfere with each other. The jig wafer 200 transmits the captured image data to the information processor 300 (step S248). The information processor 300 determines the touch position in the aligner 17 based on the received image data, and transmits it to the controller 100 (step S249). The controller 100 corrects the transfer position data of the fork 151 in the aligner 17 based on the determined touch position, and returns to the original processing.

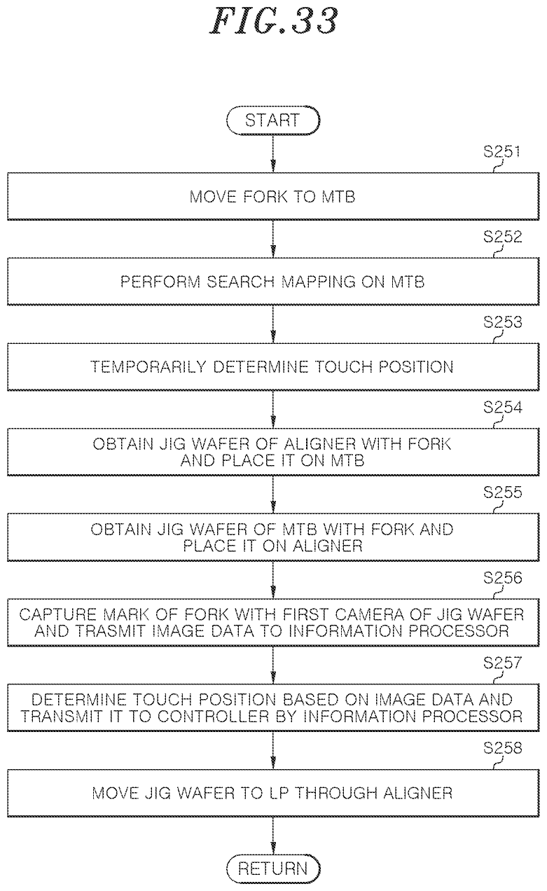

Referring back to the description of FIG. 18, the information processor 300 performs an MTB teaching process (step S25). Here, the MTB teaching process will be described with reference to FIG. 33. FIG. 33 is a flowchart showing an example of the MTB teaching process.

The information processor 300 instructs, via the controller 100, the robot arm 150 to move the fork 151 to the MTB 18. The robot arm 150 moves the fork 151 to the MTB 18 (step S251). The robot arm 150 performs the search mapping on the placing table 18a of the MTB 18 (step S252). The controller 100 temporarily determines the touch position based on the result of the search mapping (step S253).

The information processor 300 instructs, via the controller 100, the robot arm 150 to obtain the jig wafer 200 of the aligner 17 with the fork 151, place the jig wafer 200 on the MTB 18, and obtain the placed jig wafer 200 with the fork 151 again. The robot arm 150 obtains the jig wafer 200 placed on the rotation stage 17a of the aligner 17 with the fork 151, and places the jig wafer 200 on the placing table 18a of the MTB 18 (step S254).

The robot arm 150 uses the fork 151 to obtain the jig wafer 200 placed on the placing table 18a of the MTB 18, and places the jig wafer 200 on the rotation stage 17a of the aligner 17 (step S255).

When the movement of the fork 151 to the imaging position is received from the controller 100, the information processor 300 instructs the jig wafer 200 to perform imaging. The jig wafer 200 captures the marks 152 of the fork 151 with the first cameras 202a and 202b. The jig wafer 200 transmits the captured image data to the information processor 300 (step S256). The information processor 300 determines the touch position on the MTB 18 based on the received image data, and transmits it to the controller 100 (step S257). The controller 100 corrects the transfer position data of the fork 151 on the MTB 18 based on the determined touch position. The robot arm 150 moves the jig wafer 200 to the LP 16 through the aligner 17 based on the instruction from the information processor 300 (step S258), and returns to the original processing.

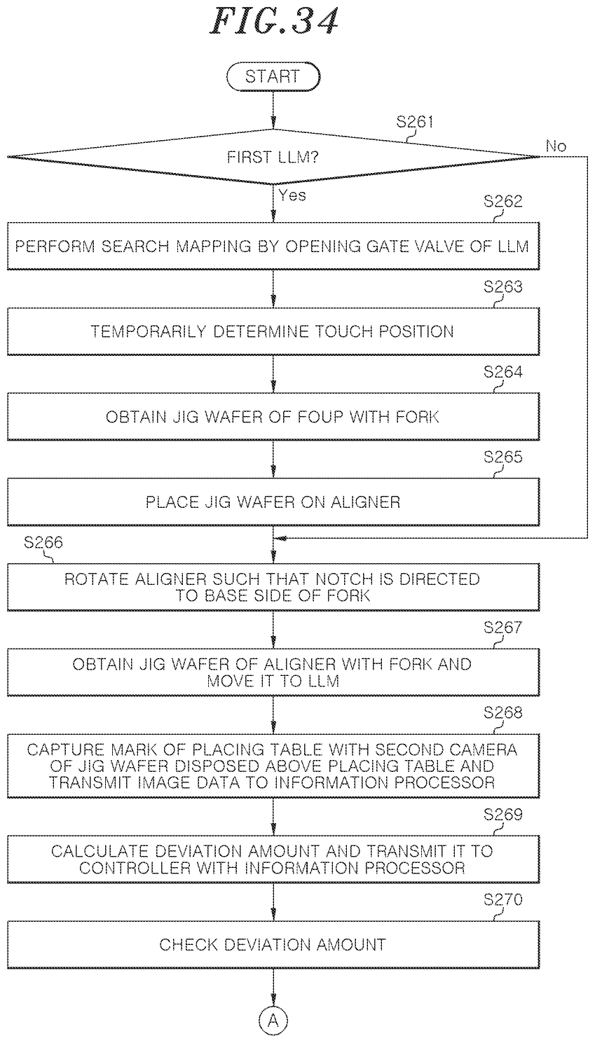

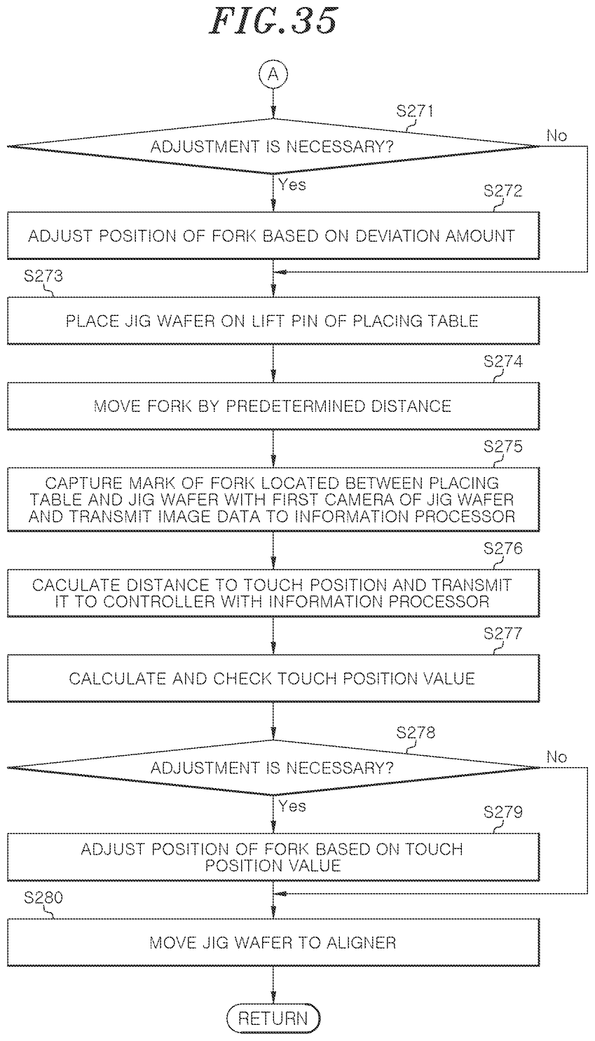

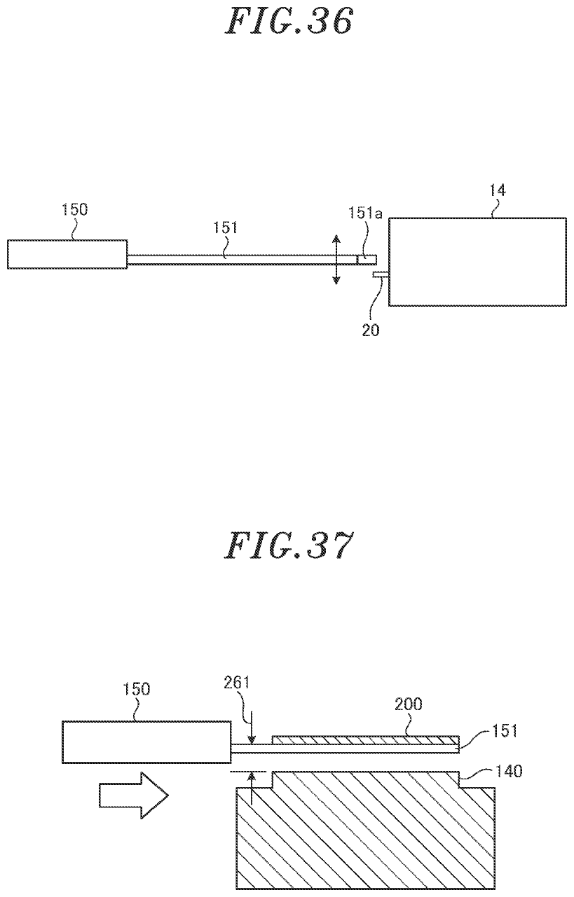

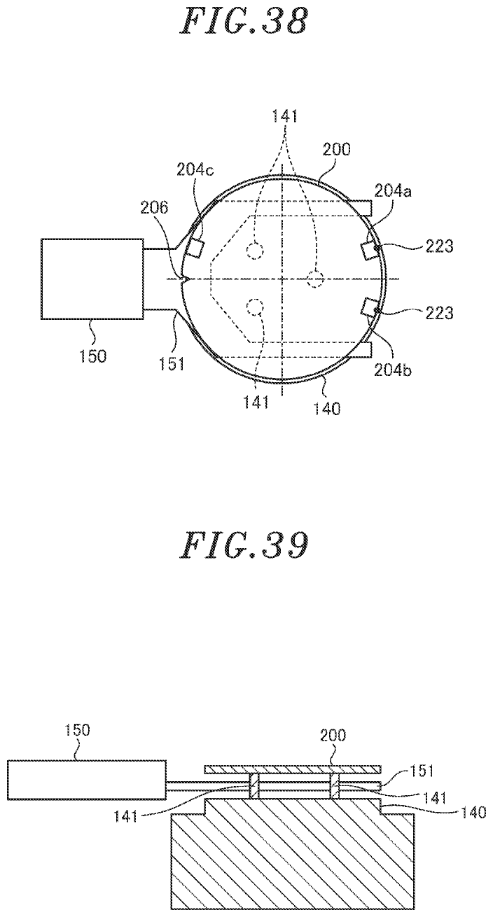

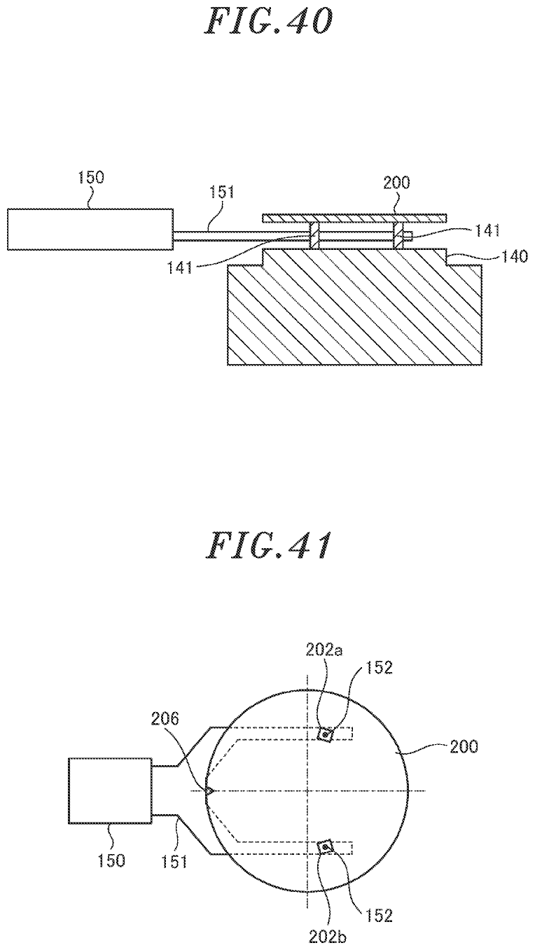

Referring back to the description of FIG. 18, the information processor 300 performs the LLM teaching process of the EFEM robot, which is teaching for the LLM 14 of the robot arm 150 (step S26). Here, the LLM teaching process of the EFEM robot will be described with reference to FIGS. 34 to 41. FIGS. 34 and 35 are flowcharts showing an example of the LLM teaching process of the EFEM robot. FIG. 36 shows an example of the search mapping for the dog of the LLM. FIG. 37 shows an example of imaging using the jig wafer disposed above the placing table of the LLM. FIG. 38 shows an example of the positional relationship between the jig wafer and the placing table in FIG. 37. FIG. 39 shows an example of a state in which the jig wafer is placed on the lift pins. FIG. 40 shows an example of imaging using the jig wafer on the lift pins. FIG. 41 shows an example of the positional relationship between the jig wafer and the fork in FIG. 40.

The information processor 300 determines whether or not the LLM 14 as a teaching target is the first LLM 14 (step S261). When it is determined that the LLM 14 is not the first LLM 14 (step S261: No), the information processor 300 proceeds to step S266.

On the other hand, when it is determined that the LLM 14 is the first LLM 14 (step S261: Yes), the information processor 300 instructs, via the controller 100, the robot arm 150 to perform the search mapping. The controller 100 opens the gate valves 143 of all the LLMs 14. When the gate valves 143 are opened, the robot arm 150 performs the search mapping for the dog 20 disposed between the LLMs 14, as shown in FIG. 36 (step S262). The controller 100 temporarily determines the touch position based on the result of the search mapping (step S263).

The information processor 300 instructs, via the controller 100, the robot arm 150 to place the jig wafer 200 from the FOUP into the aligner 17. The robot arm 150 obtains the jig wafer 200 from the FOUP with the fork 151 (step S264). The robot arm 150 moves to the aligner 17 and places the jig wafer 200 of the fork 151 on the rotation stage 17a of the aligner 17 (step S265). The controller 100 rotates the rotation stage 17a of the aligner 17 such that the notch 206 of the jig wafer 200 is directed to the base side of the fork 151 (step S266).

Based on the instruction from the information processor 300, the robot arm 150 obtains the jig wafer 200 placed on the rotation stage 17a of the aligner 17 with the fork 151, and moves it to the LLM 14 as a teaching target (step S267). As shown in FIG. 37, the robot arm 150 moves the jig wafer 200 placed on the fork 151 to the imaging position above the placing table 140 of the LLM 14. In this case, a height 261 from the top surface of the placing table 140 to the bottom surface of the jig wafer 200 is adjusted to a preset predetermined value. Further, the jig wafer 200 may transmit information indicating that the movement to the imaging position has been completed to the information processor 300 after the stationary state of the fork 151 is checked based on the data of the motion sensor 212. Further, the jig wafer 200 may transmit the data from the motion sensor 212 to the information processor 300. The data of the motion sensor 212 can also be used in other imaging processes. Further, the data may be used for performing horizontal adjustment, checking sagging of the fork 151, checking variation in contact timing, and the like, for example.

When the movement of the fork 151 to the imaging position is received from the controller 100, the information processor 300 instructs the jig wafer 200 to perform imaging. Further, when the information indicating that the movement from the jig wafer 200 to the imaging position has been completed, the information processor 300 may instruct the jig wafer 200 to perform imaging. Further, when the data of the motion sensor 212 is received from the jig wafer 200, the information processor 300 may analyze the received data to determine whether or not the jig wafer 200 is in a stationary state. When it is determined that the jig wafer 200 is in a stationary state, the information processor 300 may instruct the jig wafer 200 to perform imaging. As shown in FIG. 38, the jig wafer 200 captures the openings 223, which are the marks of the placing table 140, with the second cameras 204a and 204b. In this case, the notch 206 of the jig wafer 200 is directed to the base side of the fork 151. Further, the lift pins 141 are positioned so as not to interfere with the fork 151. The jig wafer 200 transmits the captured image data to the information processor 300 (step S268). The information processor 300 calculates the XY-axes deviation amount based on the received image data, and transmits it to the controller 100 (step S269).

The controller 100 checks whether or not the received deviation amount is within a preset allowable range (step S270). The controller 100 determines whether or not adjustment is necessary as a result of checking the deviation amount (step S271). When it is determined that the adjustment is necessary (step S271: Yes), the controller 100 adjusts the position of the fork 151 based on the deviation amount (step S272), and proceeds to step S273. In other words, the controller 100 corrects the transfer position data of the fork 151 in the LLM 14. On the other hand, when it is determined that the adjustment is not necessary (step S271: No), the controller 100 proceeds to step S273 without performing adjustment.

As shown in FIG. 39, the controller 100 raises the lift pins 141 of the placing table 140. The robot arm 150 places the jig wafer 200 on the lift pins 141 (step S273). The robot arm 150 moves the fork 151 by a predetermined distance to the position shown in FIG. 40 so that the marks 152 of the fork 151 can be captured by the first cameras 202a and 202b of the jig wafer 200 (step S274).

When the movement of the fork 151 to the imaging position is received from the controller 100, the information processor 300 instructs the jig wafer 200 to perform imaging. As shown in FIG. 41, the jig wafer 200 captures the marks 152 of the fork 151 that are located between the placing table 140 and the jig wafer 200 with the first cameras 202a and 202b. In this case, the notch 206 of the jig wafer 200 is directed to the base side of the fork 151. The jig wafer 200 transmits the captured image data to the information processor 300 (step S275). The information processor 300 calculates the distance to the touch position, i.e., the height (Z-axis) from the fork 151 to the jig wafer 200, based on the received image data, and transmits it to the controller 100 (step S276).

The controller 100 calculates a touch position value indicating the Z-axis coordinate of the touch position based on the received distance to the touch position, and checks whether or not it is within a preset allowable range (step S277). The controller 100 determines whether or not adjustment is necessary as a result of checking the touch position value (step S278). When it is determined that the adjustment is necessary (step S278: Yes), the controller 100 adjusts the position of the fork 151 based on the touch position value (step S279), and proceeds to step S280. In other words, the controller 100 corrects the transfer position data of the fork 151 in the LLM 14. On the other hand, when it is determined that the adjustment is not necessary (step S278: No), the controller 100 proceeds to step S280 without performing the adjustment.

The robot arm 150 moves the jig wafer 200 placed on the placing table 140 to the rotation stage 17a of the aligner 17 based on the instruction from the controller 100 (step S280), and returns to the original processing.

Referring back to the description of FIG. 18, when the LLM teaching process of the EFEM robot is completed, the information processor 300 determines whether or not all the LLMs 14 have completed the LLM teaching process of the EFEM robot (step S27). When it is determined that all the LLMs 14 have not completed the LLM teaching process (step S27: No), the information processor 300 returns to step S26 and performs the LLM teaching process of the EFEM robot for the remaining LLMs 14. When it is determined that all the LLMs 14 have completed the LLM teaching process (step S27: Yes), the information processor 300 instructs, via the controller 100, the robot arm 150 to move the jig wafer 200 to the FOUP of the LP 16. The robot arm 150 moves the jig wafer 200 to the FOUP of the LP 16 (step S28), and returns to the original processing.

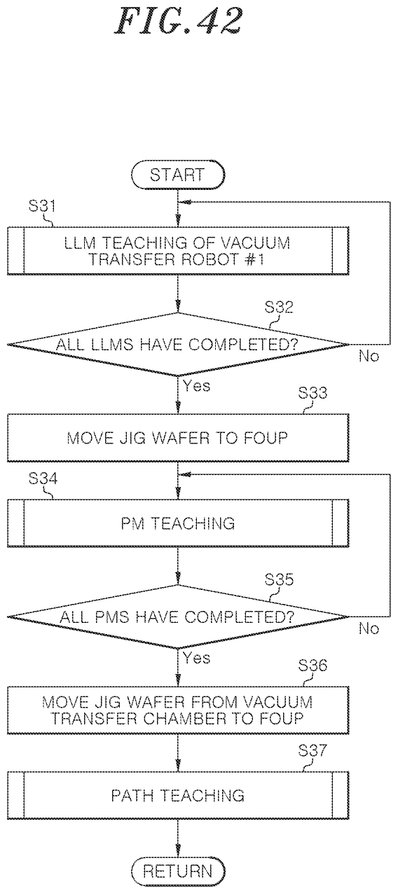

Referring back to the description of FIG. 17, the information processor 300 performs a teaching process of the vacuum transfer robot #1 in the VTM 11a (step S3). Here, the teaching process of the vacuum transfer robot #1 will be described with reference to FIG. 42. FIG. 42 is a flowchart showing an example of the teaching process of the vacuum transfer robot #1.

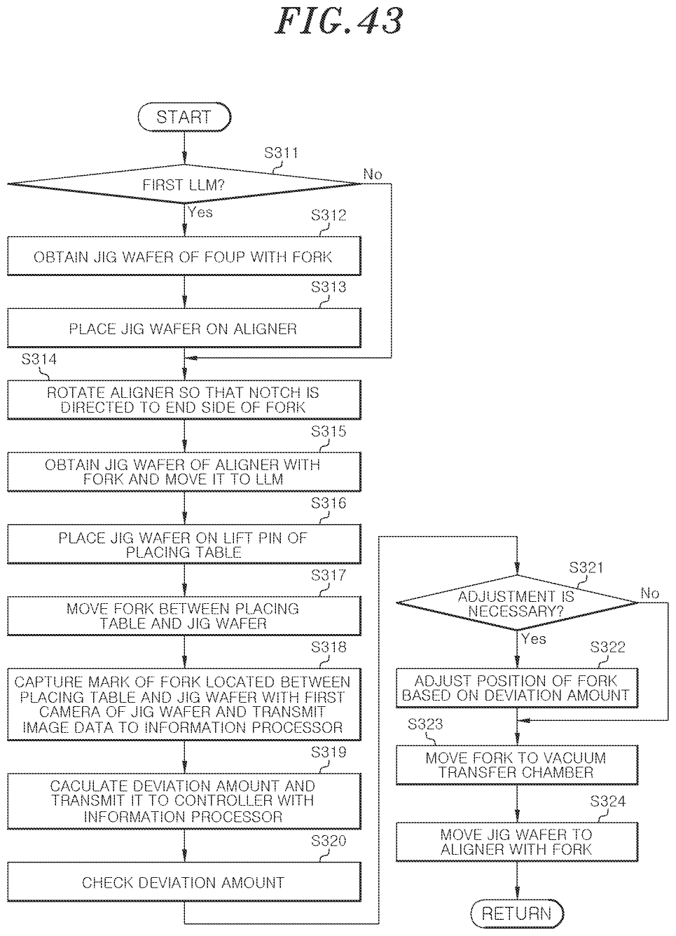

The information processor 300 performs the LLM teaching process of the vacuum transfer robot #1, which is teaching for the LLM 14 of the robot arm 12a (the vacuum transfer robot #1) of the VTM 11a (step S31). Here, the LLM teaching process of the vacuum transfer robot #1 will be described with reference to FIG. 43. FIG. 43 is a flowchart showing an example of the LLM teaching process of the vacuum transfer robot #1. The drawing showing the relationship between the jig wafer 200 and the placing table 140 is the same as the drawing showing the LLM teaching process of the EFEM robot, and thus is omitted.

The information processor 300 determines whether or not the LLM 14 as a teaching target is the first LLM 14 (step S311). When it is determined that the LLM 14 is not the first LLM 14 (step S311: No), the information processor 300 proceeds to step S314.

On the other hand, when it is determined that the LLM 14 is the first LLM 14 (step S311: Yes), the information processor 300 instructs, via the controller 100, the robot arm 150 to place the jig wafer 200 from the FOUP into the aligner 17. The robot arm 150 obtains the jig wafer 200 from the FOUP with the fork 151 (step S312). The robot arm 150 moves to the aligner 17 and places the jig wafer 200 of the fork 151 on the rotation stage 17a of the aligner 17 (step S313). The controller 100 rotates the rotation stage 17a of the aligner 17 so that the notch 206 of the jig wafer 200 is directed to the tip end side of the fork 151 (step S314).

Based on the instruction from the information processor 300, the robot arm 150 obtains the jig wafer 200 placed on the rotation stage 17a of the aligner 17 with the fork 151, and moves it to the LLM 14 as a teaching target (step S315). The controller 100 raises the lift pins 141 of the placing table 140. The robot arm 150 places the jig wafer 200 on the lift pins 141 (step S316).

The robot arm 12a of the VTM 11a moves the fork 120 to the position between the placing table 140 and the jig wafer 200 based on the instruction from the controller 100 (step S317). When the movement of the fork 120 to the imaging position is received from the controller 100, the information processor 300 instructs the jig wafer 200 to perform imaging. The jig wafer 200 captures the marks 122 of the fork 120 that are located between the placing table 140 and the jig wafer 200 with the first cameras 202a and 202b. The jig wafer 200 transmits the captured image data to the information processor 300 (step S318). The information processor 300 calculates the XYZ-axes deviation amount based on the received image data, and transmits it to the controller 100 (step S319).

The controller 100 checks whether or not the received deviation amount is within a preset allowable range (step S320). The controller 100 determines whether or not adjustment is necessary as a result of checking the deviation amount (step S321). When it is determined that the adjustment is necessary (step S321: Yes), the controller 100 adjusts the position of the fork 120 based on the deviation amount (step S322), and proceeds to step S323. In other words, the controller 100 corrects the transfer position data of the fork 120 in the LLM 14. On the other hand, when it is determined that the adjustment is not necessary (step S321: No), the controller 100 proceeds to step S323 without performing the adjustment.

The robot arm 12a of the VTM 11a moves the fork 120 from the LLM 14 to the VTM 11a based on the instruction from the controller 100 (step S323). Based on the instruction from the controller 100, the robot arm 150 of the EFEM 15 obtains the jig wafer 200 placed on the lift pins 141 with the fork 151, moves the jig wafer 200 to the rotation stage 17a of the aligner 17 (step S324), and returns to the original processing.

Referring back to the description of FIG. 42, when the LLM teaching process of the vacuum transfer robot #1 is completed, the information processor 300 determines whether or not all the LLMs 14 have completed the LLM teaching process of the vacuum transfer robot #1 (step S32). When it is determined that all the LLMs 14 have not completed the LLM teaching process (step S32: No), the information processor 300 returns to step S31 and performs the LLM teaching process of the vacuum transfer robot #1 for the remaining LLMs 14. When it is determined that all the LLMs 14 have completed the LLM teaching process (step S32: Yes), the information processor 300 instructs, via the controller 100, the robot arm 150 to move the jig wafer 200 to the FOUP. The robot arm 150 moves the jig wafer 200 to the FOUP (step S33).

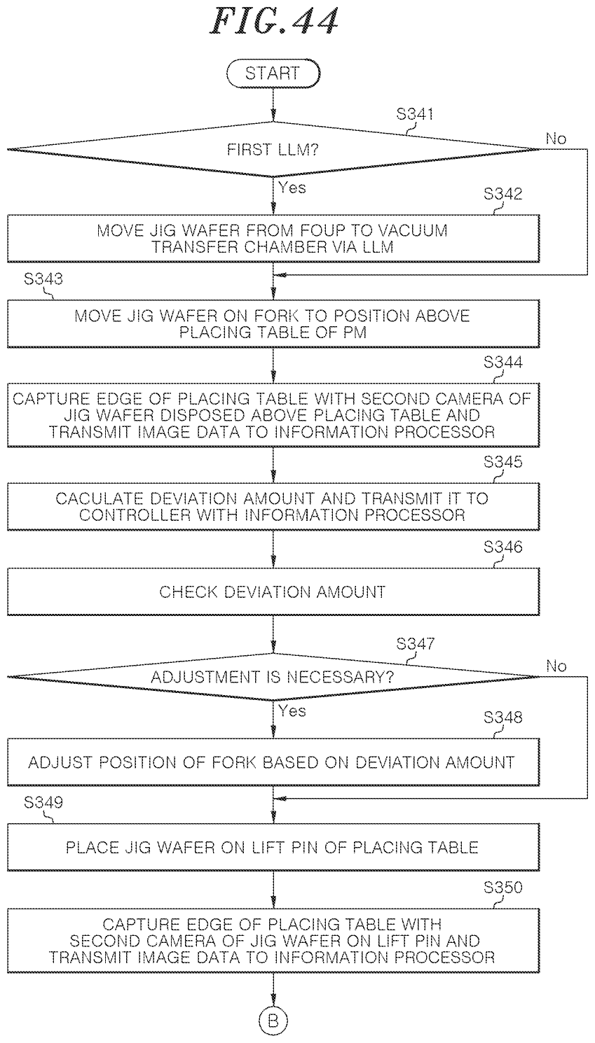

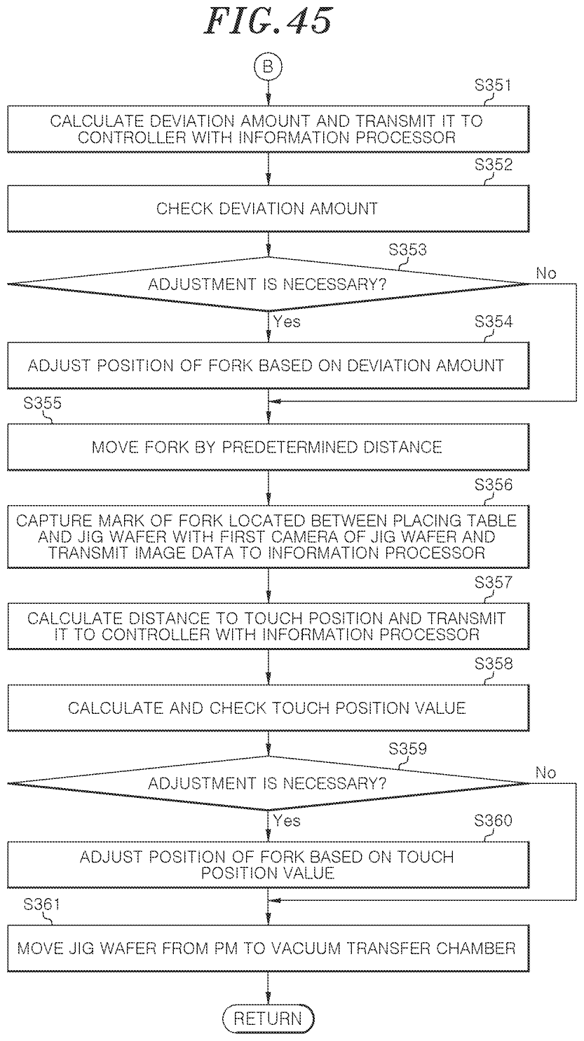

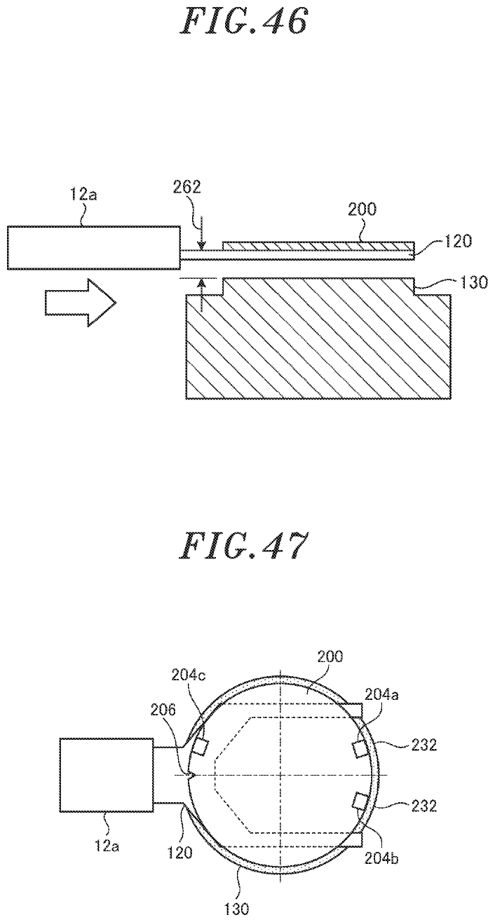

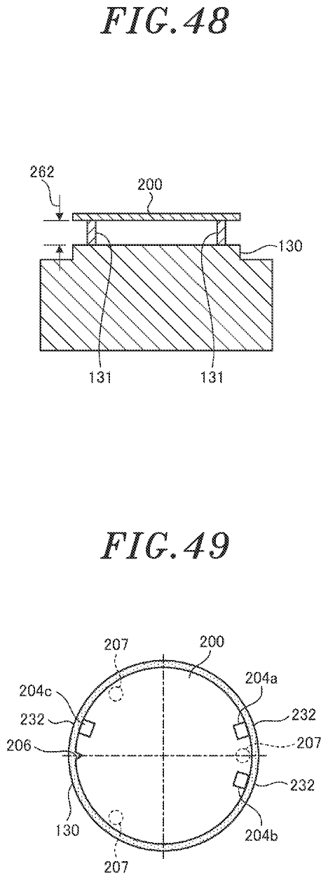

The information processor 300 performs a PM teaching process (step S34). Here, the PM teaching process will be described with reference to FIGS. 44 to 49. FIGS. 44 and 45 are flowcharts showing an example of the PM teaching process. FIG. 46 shows an example of imaging using the jig wafer disposed above the placing table of the PM. FIG. 47 shows an example of the positional relationship between the jig wafer and the placing table in FIG. 46. FIG. 48 shows an example of imaging using the jig wafer on the lift pins. FIG. 49 shows an example of the positional relationship between the jig wafer and the placing table in FIG. 48.

The information processor 300 determines whether the PM 13 as a teaching target is the first PM 13 (step S341). When it is determined that the PM 13 as a teaching target is not the first PM 13 (step S341: No), the information processor 300 proceeds to step S343.

On the other hand, when it is determined that the PM 13 as a teaching target is the first PM 13 (step S341: Yes), the information processor 300 instructs, via the controller 100, the robot arms 150 and 12a to move the jig wafer 200 to the VTM 11a through the LLMM 14. The robot arms 150 and 12a move the jig wafer 200 from the FOUP of the LP 16 to the VTM 11a via the LLM 14 (step S342).

As shown in FIG. 46, the robot arm 12a of the VTM 11a moves the jig wafer 200 on the fork 120 to the imaging position above the placing table 130 of the PM 13 (step S343). In this case, a height 262 from the top surface of the placing table 130 to the bottom surface of the jig wafer 200 is adjusted to a preset predetermined value. Further, the jig wafer 200 may transmit information indicating that the movement to the imaging position has been completed to the information processor 300 after checking the stationary state of the fork 120 based on the data of the motion sensor 212. Further, the jig wafer 200 may transmit the data of the motion sensor 212 to the information processor 300. The data of the motion sensor 212 can also be used in other imaging processes. Further, the data may be used for performing horizontal adjustment, checking sagging of the fork 120, checking variation in contact timing, and the like, for example.

When the movement of the fork 120 to the imaging position is received from the controller 100, the information processor 300 instructs the jig wafer 200 to perform imaging. Further, when the information indicating that the movement from the jig wafer 200 to the imaging position has been completed is received, the information processor 300 may instruct the jig wafer 200 to perform imaging. Further, when the data of the motion sensor 212 is received from the jig wafer 200, the information processor 300 may analyze the received data to determine whether or not the jig wafer 200 is in a stationary state. When it is determined that the jig wafer 200 is in a stationary state, the information processor 300 may instruct the jig wafer 200 to perform imaging. As shown in FIG. 47, the jig wafer 200 captures the edges 232 of the placing table 130 with the second cameras 204a and 204b. In this case, the notch 206 of the jig wafer 200 is directed to the base side of the fork 120. The jig wafer 200 transmits the captured image data to the information processor 300 (step S344). The information processor 300 calculates the XY-axes deviation amount based on the received image data, and transmits it to the controller 100 (step S345).

The controller 100 checks whether or not the received deviation amount is within a preset allowable range (step S346). The controller 100 determines whether or not adjustment is necessary as a result of checking the deviation amount (step S347). When the controller 100 determines that the adjustment is necessary (step S347: Yes), the controller 100 adjusts the position of the fork 120 based on the deviation amount (step S348), and proceeds to step S349. In other words, the controller 100 corrects the transfer position data of the fork 120 in the PM 13. On the other hand, when it is determined that the adjustment is not necessary (step S347: No), the controller 100 proceeds to step S349 without performing the adjustment.

As shown in FIG. 48, the controller 100 raises the lift pins 131 of the placing table 130. The robot arm 12a places the jig wafer 200 on the lift pins 131 (step S349). On the lift pins 131, the height 262 from the top surface of the placing table 130 to the bottom surface of the jig wafer 200 is the same as that in the case of the fork 120.

When the placement of the jig wafer 200 on the lift pins 131 is received from the controller 100, the information processor 300 retracts the fork 120 from the position below the jig wafer 200, and instructs the jig wafer 200 to perform imaging. As shown in FIG. 49, the jig wafer 200 captures the edges 232 of the placing table 130 with the second cameras 204a, 204b, and 204c. The jig wafer 200 transmits the captured image data to the information processor 300 (step S350). The information processor 300 calculates the XY-axes deviation amount based on the received image data, and transmits it to the controller 100 (step S351). The jig wafer 200 may be provided with contact sensors 207 corresponding to the lift pins 131, and may perform imaging after the contact of the lift pins 131 is checked by all the contact sensors 207.

The controller 100 checks whether or not the received deviation amount is within a preset allowable range (step S352). The controller 100 determines whether or not adjustment is necessary as a result of checking the deviation amount (step S353). When it is determined that the adjustment is necessary (step S353: Yes), the controller 100 adjusts the position of the fork 120 based on the deviation amount (step S354), and proceeds to step S355. In other words, the controller 100 corrects the transfer position data of the fork 120 in the PM 13. On the other hand, when it is determined that the adjustment is not necessary (step S353: No), the controller 100 proceeds to step S355 without performing the adjustment.

The robot arm 12a moves the fork 120 by a predetermined distance so that the marks 122 of the fork 120 can be captured by the first cameras 202a and 202b of the jig wafer 200 (step S355).

When the movement of the fork 120 to the imaging position is received from the controller 100, the information processor 300 instructs the jig wafer 200 to perform imaging. The jig wafer 200 captures the marks 122 of the fork 120 that are located between the placing table 130 and the jig wafer 200 with the first cameras 202a and 202b. The jig wafer 200 transmits the captured image data to the information processor 300 (step S356). The information processor 300 calculates the distance to the touch position, that is, the height (Z-axis) from the fork 120 to the jig wafer 200, based on the received image data, and transmits it to the controller 100 (step S357).

The controller 100 calculates a touch position value representing the Z-axis coordinate of the touch position based on the received distance to the touch position, and checks whether or not it is within a preset allowable range (step S358). The controller 100 determines whether or not adjustment is necessary as a result of checking the touch position value (step S359). When it is determined that the adjustment is necessary (step S359: Yes), the controller 100 adjusts the position of the fork 120 based on the touch position value (step S360), and proceeds to step S361. In other words, the controller 100 corrects the transfer position data of the fork 120 in the PM 13. On the other hand, when it is determined that the adjustment is not necessary (step S360: No), the controller 100 proceeds to step S361 without performing the adjustment.

The robot arm 12a moves the jig wafer 200 placed on the placing table 130 from the PM 13 to the VTM 11a based on the instruction from the controller 100 (step S361), and returns to the original processing.

Referring back to the description of FIG. 42, when the PM teaching process is completed, the information processor 300 determines whether or not all the PMs 13 connected to the VTM 11a have completed the PM teaching process (step S35). When the information processor 300 determines that all the PMs 13 connected to the VTM 11a have not completed the PM teaching process (step S35: No), the information processor 300 returns to step S34 and performs the PM teaching process for the remaining PMs 13. When the information processor 300 determines that all the PMs 13 connected to the VTM 11a have completed the PM teaching process (step S35: Yes), the information processor 300 instructs, via the controller 100, the robot arms 12a and 150 to move the jig wafer 200 form the VTM 11a to the FOUP of the LP 16 through the LLM 114 and the aligner 17. The robot arms 12a and 150 move the jig wafer 200 from the VTM 11a to the FOUP of the LP 16 through the LLM 14 and the aligner 17 (step S36).

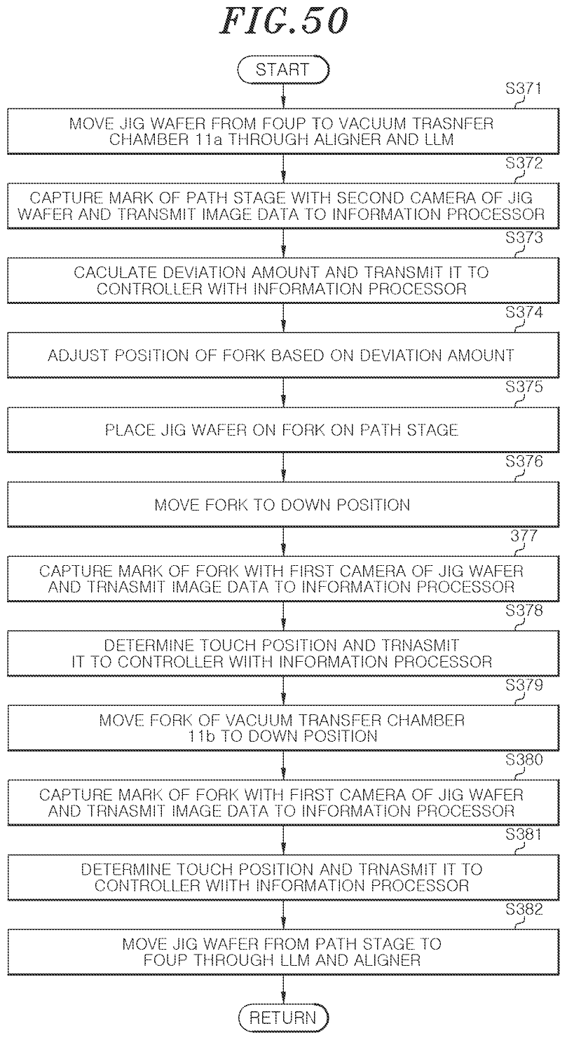

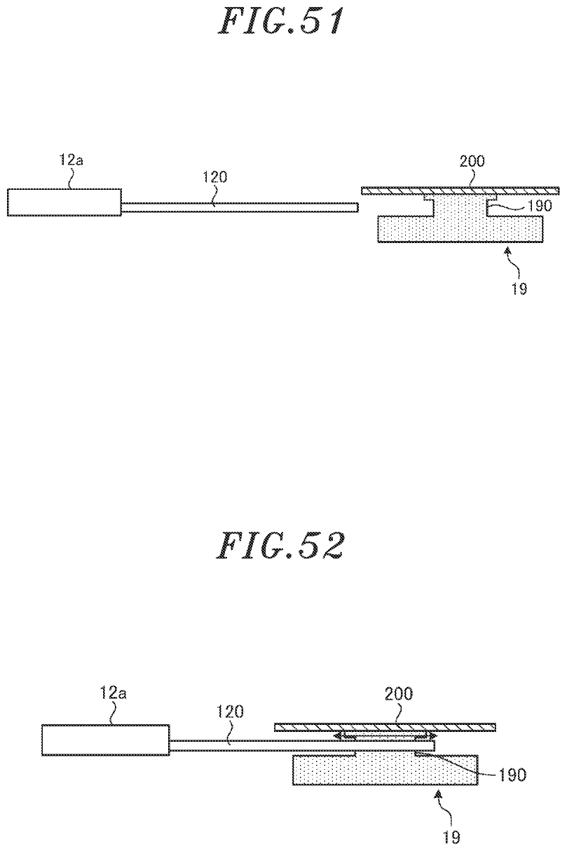

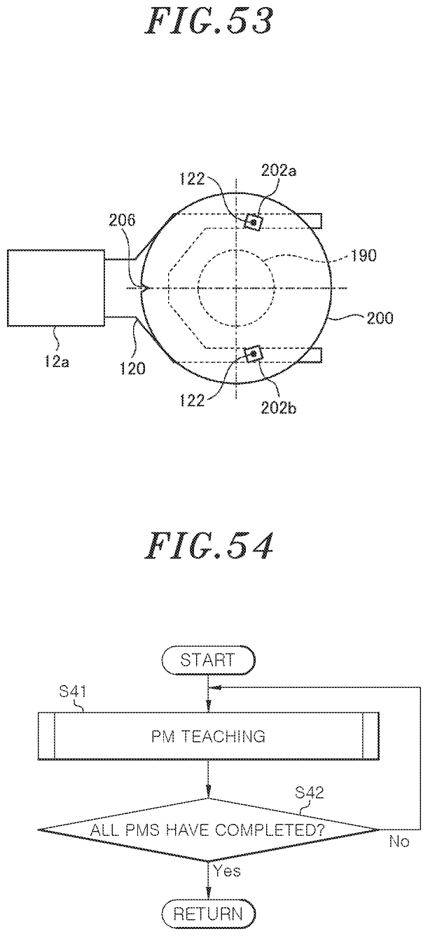

The information processor 300 performs a path teaching process (step S37). Here, the path teaching process will be described with reference to FIGS. 50 to 53. FIG. 50 is a flowchart showing an example of the path teaching process. FIG. 51 shows an example of a state in which the jig wafer is placed on the path. FIG. 52 shows an example of imaging using the jig wafer placed on the path. FIG. 53 shows an example of the positional relationship between the jig wafer and the fork in FIG. 52.

The information processor 300 instructs, via the controller 100, the robot arms 150 and 12a to move the jig wafer 200 from the FOUP to the VTM 11a (VTM #1) through the aligner 17 and the LLM 14. The robot arms 150 and 12a move the jig wafer 200 from the FOUP of the LP 16 to the VTM 11a (VTM #1) through the aligner 17 and the LLM 14 (step S371).

The robot arm 12a of the VTM 11a (VTM #1) moves the jig wafer 200 placed on the fork 120 to the imaging position above the path stage 190 of the path 19. When the movement of the fork 120 to the imaging position is received from the controller 100, the information processor 300 instructs the jig wafer 200 to perform imaging. The jig wafer 200 captures the marks disposed at the peripheral portion of the path stage 190 with the second cameras 204a and 204b. The jig wafer 200 transmits the captured image data to the information processor 300 (step S372). The information processor 300 calculates the XY-axes deviation amount based on the received image data, and transmits it to the controller 100 (step S373). The controller 100 adjusts the position of the fork 120 in the path 19 based on the received deviation amount (step S374). As shown in FIG. 51, the robot arm 12a places the jig wafer 200 on the fork 120 on the path stage 190 of the path 19 (step S375). As shown in FIG. 52, the robot arm 12a moves the fork 120 to the down position of the touch position so that the marks 122 of the fork 120 can be captured by the first cameras 202a and 202b of the jig wafer 200 (step S376).

When the movement of the fork 120 of the VTM 11a (VTM #1) to the imaging position is received from the controller 100, the information processor 300 instructs the jig wafer 200 to perform imaging. As shown in FIG. 53, the jig wafer 200 captures the marks 122 of the fork 120 with the first cameras 202a and 202b. In this case, the notch 206 of the jig wafer 200 is directed to the base side of the fork 120. Further, the teeth of the fork 120 and the path stage 190 are positioned so as not to interfere with each other. The jig wafer 200 transmits the captured image data to the information processor 300 (step S377). The information processor 300 determines the touch position on the VTM 11a (VTM #1) side in the path 19 based on the received image data, and transmits it to the controller 100 (step S378). The controller 100 corrects the transfer position data of the fork 120 of the robot arm 12a in the path 19.

The information processor 300 returns, via the controller 100, the robot arm 12a to the VTM 11a (VTM #1) side, and instructs teaching of the robot arm 12b of the VTM 11b (VTM #2). The robot arm 12b moves the fork 120 to the down position of the touch position so that the marks 122 of the fork 120 can be captured by the first cameras 202a and 202b of the jig wafer 200 placed on the path stage 190 (step S379).

When the movement of the fork 120 of the VTM 11b (VTM #2) to the imaging position is received from the controller 100, the information processor 300 instructs the jig wafer 200 to perform imaging. The jig wafer 200 captures the marks 122 of the fork 120 with the first cameras 202a and 202b. In this case, the notch 206 of the jig wafer 200 is directed to the base side of the fork 120 of the robot arm 12a, so that the positions of the marks 122 of the fork 120 of the robot arm 12b are also aligned with the direction of the notch 206. In other words, the positions of the marks 122 of the fork 120 of the robot arm 12b are opposite to those of the fork 120 of the robot arm 12a. Further, the teeth of the fork 120 and the path stage 190 are positioned so as not to interfere with each other. The jig wafer 200 transmits the captured image data to the information processor 300 (step S380). The information processor 300 determines the touch position on the VTM 11b (VTM #2) side in the path 19 based on the received image data, and transmits it to the controller 100 (step S381). The controller 100 corrects the transfer position data of the fork 120 of the robot arm 12b in the path 19.

The robot arm 12b moves the fork 120 to the VTM 11b (VTM #2) side based on the instruction from the information processor 300. Further, the robot arm 12a obtains the jig wafer 200 from the path stage 190 of path 19 based on the instruction from the information processor 300. The robot arms 12a and 150 move the jig wafer 200 from the path 19 to the FOUP through the LLM 14 and the aligner 17 based on the instruction from the information processor 300 (step S382), and return to the original processing.

Referring back to the description of FIG. 42, when the path teaching process is completed, the teaching process of the vacuum transfer robot #1 is also completed, so that the information processor 300 returns to the original processing.

Referring back to the description of FIG. 17, the information processor 300 performs a teaching process of the vacuum transfer robot #2 of the vacuum transfer chamber 11b (step S4). Here, the teaching process of the vacuum transfer robot #2 will be described with reference to FIG. 54. FIG. 54 is a flowchart showing an example of the teaching process of the vacuum transfer robot #2.

The information processor 300 performs the PM teaching process (step S41). The PM teaching process in step S41 is the same as the PM teaching process in step S34 shown in FIG. 42 except that the jig wafer 200 is transferred to the VTM 11b (VTM #2), so that the description thereof will be omitted.

When the PM teaching process is completed, the information processor 300 determines whether or not all the PMs 13 connected to the VTM 11b (VTM #2) have completed the PM teaching process (step S42). When it is determined that all the PMs 13 connected to the VTM 11b have not completed the PM teaching process (step S42: No), the information processor 300 returns to step S41 and performs the PM teaching process for the remaining PMs 13. When it is determined that all the PMs 13 connected to the VTM 11b have completed the PM teaching process (step S42: Yes), the information processor 300 returns the jig wafer 200 to the FOUP of the LP 16, thereby returning to the original process.

Referring back to the description of FIG. 17, when the teaching process of the vacuum transfer robot #2 of the vacuum transfer chamber 11b is completed, it is considered that the teaching of the substrate processing system 1 is completed, so that the information processor 300 terminates the teaching process. In the present embodiment, the accuracy of the transfer position including the height direction can be improved in each module of the substrate processing system 1. Further, the labor of the teaching process can be saved. Moreover, the time required for the teaching process can be shortened.

### [Modification]

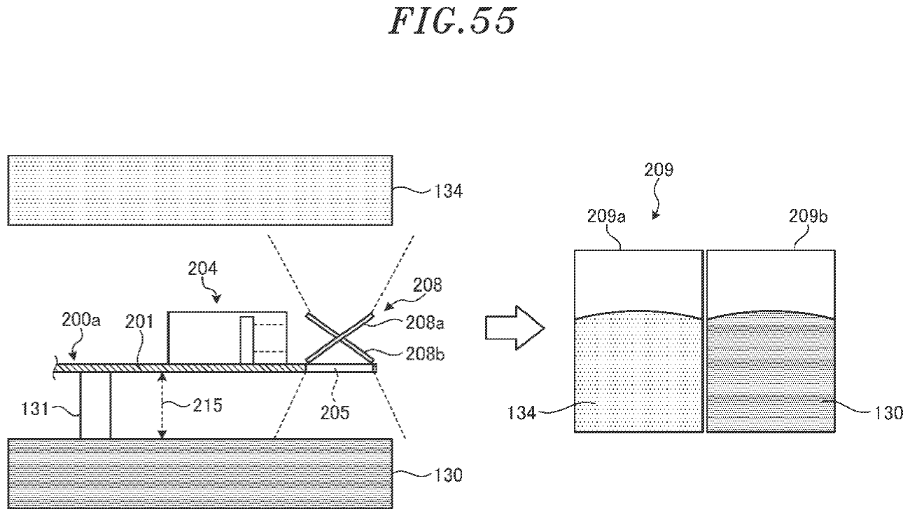

In the above-described embodiment, the first camera 202 and the second camera 204 of the jig wafer 200 are arranged to capture the lower side of the jig wafer 200 through the prisms 203a and 205a. However, the present disclosure is not limited thereto. For example, a prism or a mirror may be combined to capture the upper side and the lower side of the jig wafer 200. Such a case will be described with reference to FIG. 55. FIG. 55 shows an example of the jig wafer and the captured image in a modification.

FIG. 55 shows a state in which a jig wafer 200a is placed on the lift pins 131 on the placing table 130 of the PM 13. In this case, the jig wafer 200a is placed at a predetermined height 215 so that the edges of the placing table 130 can be captured.

As shown in FIG. 55, the jig wafer 200a has a mirror part 208 instead of the prism 205a. The mirror part 208 includes a mirror 208a capable of imaging the upper side of the jig wafer 200a, and a mirror 208b capable of imaging the lower side of the jig wafer 200a. The second camera 204 can capture a shower plate 134, which is disposed above the placing table 130 to face the placing table 130, through the mirror 208a. Further, the second camera 204 can capture the placing table 130 through the mirror 208b and the opening 205. An image 209 captured by the second camera 204 of the jig wafer 200a has a region 209a corresponding to the mirror 208a and a region 209b corresponding to the mirror 208b. In the region 209a, the shower plate 134 is captured. In the region 209b, the placing table 130 is captured. The prism 203a may also be replaced with the mirror part 201. By using the mirrors 208a and 208b capable of imaging the upper side and the lower side, the accuracy of the transfer position can also be improved in the positional relationship with the shower plate 134 as well as the placing table 130.

As described above, in accordance with the present embodiment, the jig substrate (the jig wafer 200) is used in the teaching method for the transfer mechanism (the robot arms 12a, 12b, and 150), and includes the first camera 202 and the second camera 204. The first camera 202 captures first image data for detecting the position of the fork (the forks 120 and 151) of the transfer mechanism. The second camera 204 captures second image data for detecting the position of the placing table (the placing tables 130 and 140) on which the substrate is placed. Accordingly, the accuracy of the transfer position including the height direction can be improved.

Further, in accordance with the present embodiment, the first camera 202 captures the first image data for adjusting the position of the fork with respect to the substrate placed on the placing table based on the detected position of the fork. Accordingly, the position of the fork including the height direction (Z-axis) can be adjusted.

Further, in accordance with the present embodiment, the first image data includes the position detection marks disposed at the fork. Accordingly, the position of the fork including the height direction (Z-axis) can be adjusted based on the marks.

Further, in accordance with the present embodiment, the first camera 202 captures the first image data including the marks of the fork that are located between the placing table and the placing table in a state where the jig substrate placed on the placing table is lifted from the placing table by the lift pins (the lift pins 131 and 141). Accordingly, the position of the fork including the height direction (Z-axis) can be adjusted based on the marks.

Further, in accordance with the present embodiment, the first camera 202 captures the first image data for adjusting the position of the fork in the Z-axis direction. Accordingly, the position of the fork including the height direction (Z-axis) can be adjusted.

Further, in accordance with the present embodiment, the second camera 204 captures the second image data for adjusting the position of the fork with respect to the placing table based on the detected position of the placing table. Accordingly, the accuracy of the transfer position of the fork with respect to the placing table can be improved.

Further, in accordance with the present embodiment, the second image data includes the ends of the placing table for detecting the position of the placing table. Accordingly, the accuracy of the transfer position of the fork with respect to the placing table can be improved.

Further, in accordance with the present embodiment, the second camera 204 captures the second image data for adjusting the positions of the fork in the X-axis direction and the Y-axis direction. Accordingly, the accuracy of the transfer position of the fork with respect to the placing table can be improved.

Further, in accordance with the present embodiment, each of the first camera 202 and the second camera 204 is provided in plural number. Accordingly, the accuracy of the transfer position including the height direction can be further improved.

Further, in accordance with the present embodiment, the jig substrate further includes the motion sensor 212 for detecting the stationary state of the jig substrate at the time of capturing the first image data or the second image data. Accordingly, the stationary state of the jig wafer 200 can be checked, which makes it possible to further improve the accuracy of the transfer position including the height direction.

Further, in accordance with the present embodiment, the teaching method is used for the transfer mechanism (the robot arms 12a, 12b, and 150), and includes: moving the fork (the forks 120 and 151) of the transfer mechanism to the position below the jig substrate (the jig wafer 200) supported by the support (the slot, the rotation stage 17a, the placing table 18a, the lift pins 131 and 141, and the path stage 190); capturing first image data including the position detection marks (the marks 122 and 152) disposed at the fork with the first cameras 202 disposed at the jig substrate; determining the destination position of the fork based on the first image data; and correcting the transfer position data of the fork based on the determined destination position of the fork. Accordingly, the accuracy of the transfer position including the height direction can be improved.

Further, in accordance with the present embodiment, in the determining step, the destination positions of the fork in the X-axis direction and the Y-axis direction are determined based on the marks. Accordingly, the accuracy of the transfer position of the fork in the X-axis direction and the Y-axis direction can be improved.

Further, in accordance with the present embodiment, in the determining step, the destination position of the folk in the Z-axis direction is determined based on the marks. Accordingly, the accuracy of the transfer position of the fork in the Z-axis direction can be improved.

Further, in accordance with the present embodiment, the teaching method further includes: moving the fork on which the jig substrate is placed to the position above the placing table on which the substrate is placed; capturing the second image data including the ends (the edges 232) of the placing table) or the marks (the openings 223) disposed at the placing table with the second cameras 204; determining the position of the fork with respect to the placing table based on the second image data; and correcting the destination position of the fork based on the determined position of the fork with respect to the placing table. Accordingly, the accuracy of the transfer position of the fork with respect to the placing table can be improved.

Further, in accordance with the present embodiment, in the step of determining the position of the fork with respect to the placing table, the positions of the fork in the X-axis direction and the Y-axis direction are determined based on the ends or the marks. Accordingly, the accuracy of the transfer position of the fork with respect to the placing table can be improved.

Further, in accordance with the present embodiment, the placing tables are placing tables (the placing tables 140 and 130) disposed in the load-lock modules 14 or the process modules 13. Accordingly, the accuracy of the transfer position of the fork in the load-lock modules 14 or the process modules 13 can be improved.

Further, in accordance with the present embodiment, the teaching method further includes, after the step of moving the fork on which the jig substrate is placed, determining whether or not the jig substrate is in a stationary state based on data of the motion sensor 212 for detecting the stationary state of the jig substrate disposed at the jig substrate, and instructing imaging of the second image data when it is determined that the jig substrate is in the stationary state. Accordingly, the accuracy of the transfer position can be further improved.

Further, in accordance with the present embodiment, the support includes the slots in the container accommodating the substrate to be placed on the load port 16, the rotation stage 17a of the aligner 17, the lift pins (the lift pins 131 and 141) for lifting the substrate from the placing table, or the stage (the path stage 190) of the path 19. Accordingly, it is possible to improve the accuracy of the transfer position including the height direction in each module.

It should be noted that the embodiments of the present disclosure are illustrative in all respects and are not restrictive. The above-described embodiments may be omitted, replaced, or changed in various forms without departing from the scope of the appended claims and the gist thereof.

Further, in the above-described embodiments, the case in which the teaching is performed for individual components of the processing system body 10 at once has been described. However, the present disclosure is not limited thereto. For example, the teaching of the VTMs 11a and 11b, the PMs 13, the LLMs 14, the EFEM 15, the LPs 16, the aligner 17, the MTB 18, and the path 19 may be performed individually during maintenance or the like.

### DESCRIPTION OF REFERENCE NUMERALS

1: substrate processing system

5: robot controller

10: processing system body

11a, 11b: vacuum transfer chamber (VTM)

12a, 12b, 150: robot arm

13: process module (PM)

14: load-lock module (LLM)

15: EFEM

16: load port (LP)

17: aligner

17a: rotation stage

18a, 130, 140: placing table

19: path

20: dog

100: controller

120, 151: fork

122, 152: mark

131, 141: lift pin

190: path stage

200: jig wafer

202: first camera

203a, 205a: Prism

204: second camera

210: controller

211: communication part

212: motion sensor

213: battery

223: opening

232: cdgc

300: information processor

1. A jig substrate used in a teaching method for a transfer mechanism, comprising:
a first camera configured to capture first image data for detecting a position of a fork of the transfer mechanism; and
a second camera configured to capture second image data for detecting a position of a placing table on which a substrate is placed.

2. The jig substrate of claim 1, wherein the first camera captures the first image data for adjusting the position of the fork with respect to the substrate placed on the placing table based on the detected position of the fork.

3. The jig substrate of claim 2, wherein the first image data includes a position detection mark disposed at the fork.

4. The jig substrate of claim 3, wherein the first camera captures the first image data including the position detection mark of the fork positioned between the jig substrate and the placing table in a state where the jig substrate placed on the placing table is lifted by a lift pin configured to lift the jig substrate from the placing table.

5. The jig substrate of claim 2, wherein the first camera captures the first image data for adjusting the position of the fork in a Z-axis direction.

6. The jig substrate of claim 1, wherein the second camera captures the second image data for adjusting the position of the fork with respect to the placing table based on the detected position of the placing table.

7. The jig substrate of claim 6, wherein the second image data includes an end of the placing table for detecting the position of the placing table.

8. The jig substrate of claim 6, wherein the second camera captures the second image data for adjusting the position of the fork in a X-axis direction and a Y-axis direction.

9. The jig substrate of claim 1, wherein the first camera is provided in plural number and the second camera is provided in plural number.

10. The jig substrate of claim 1, further comprising:
a motion sensor configured to detect a stationary state of the jig substrate at a time of capturing the first image data or the second image data.

11. A teaching method for a transfer mechanism, comprising:
moving a fork of the transfer mechanism to a position below a jig substrate supported by a support;
capturing first image data including a position detection mark disposed at the fork with a first camera disposed at the jig substrate;
determining a destination position of the fork based on the first image data;
correcting transfer position data of the fork based on the determined destination position of the fork.

12. The teaching method of claim 11, wherein in said determining, destination positions of the fork in a X-axis direction and a Y-axis direction are determined based on the position detection mark.

13. The teaching method of claim 11, wherein in said determining, destination position of the fork in a Z-axis direction is determined based on the position detection mark.

14. The teaching method of claim 11, further comprising:
moving the fork on which the jig substrate is placed to a position above a placing table for placing a substrate thereon;
capturing second image data including an end of the placing table or a mark disposed at the placing table with a second camera disposed at the jig substrate;
determining a position of the fork with respect to the placing table based on the second image data; and
correcting the transfer position data of the fork based on the determined position of the fork with respect to the placing table.

15. The teaching method of claim 14, wherein in said determining the position of the fork with respect to the placing table, positions of the fork in a X-axis direction and a Y-axis direction are determined based on the end or the position detection mark.

16. The teaching method of claim 14, wherein the placing table is a placing table of a load-lock module or a process module.

17. The teaching method of claim 14 any one of claims 14 to 16, further comprising:
after said moving the fork on which the jig substrate is placed, determining whether or not the jig substrate is in a stationary state based on data of a motion sensor which is provided at the jig substrate and configured to detect a stationary state of the jig substrate and instructing capturing of the second image data when it is determined that the jig substrate is in the stationary state.

18. The teaching method of claim 14, wherein the support is a slot in a container which is placed on a load port and configured to accommodate the substrate, a rotation stage of an aligner, a lift pin configured to lift the substrate from a placing table, or a stage of a path.
